(19) United States
(12) Patent Application Publication
(10) Pub. No.: US 2024/0387402 A1
(43) Pub. Date: Nov. 21, 2024

(54) SEMICONDUCTOR DEVICE, MANUFACTURING METHOD, AND MEMORY SYSTEM

(71) Applicant: YANGTZE MEMORY TECHNOLOGIES CO., LTD., Wuhan (CN)

(72) Inventors: Wei XIE, Wuhan (CN); Jing ZHANG, Wuhan (CN); Yaqin LIU, Wuhan (CN); Guozhu MEI, Wuhan (CN); Lei LIU, Wuhan (CN); Kun ZHANG, Wuhan (CN)

(21) Appl. No.: 18/484,286

(22) Filed: Oct. 10, 2023

(30) Foreign Application Priority Data
May 18, 2023 (CN) 202310576499X

(51) Int. Cl. H01L 23/00; H01L 23/58; H01L 25/00; H01L 25/065; H01L 25/18; H10B 41/27; H10B 43/27; H10B 80/00

(52) U.S. Cl. CPC H01L 23/562; H01L 23/585; H01L 25/0657; H01L 25/18; H01L 25/50; H10B 41/27; H10B 43/27; H10B 80/00; H01L 2225/06513

(57) ABSTRACT

Examples of the present disclosure provide a semiconductor device, a manufacturing method thereof, and a memory system. The semiconductor device comprises: a stacking structure comprising a memory array area and a first sealing area; and at least one circle of sealing structure in the first sealing area and surrounding the memory array area, wherein the sealing structure comprises a sealing ring body penetrating through the stacking structure and at least two circles of first dummy interconnection structures connected with the sealing ring body.

### CROSS-REFERENCE TO RELATED APPLICATIONS

The present application claims priority to Chinese Patent Application No. 202310576499X, which was filed May 18, 2023, is titled “SEMICONDUCTOR DEVICE AND ITS MANUFACTURING METHOD, MEMORY SYSTEM,” and is hereby incorporated herein by reference in its entirety.

### TECHNICAL FIELD

The present disclosure relates to a field of semiconductor technology, more specifically, to a semiconductor device, a manufacturing method thereof, and a memory system.

### BACKGROUND

In the manufacturing process of a semiconductor device (e.g., a three-dimensional (3D) NAND memory), dividing multiple dies into individual dies may lead to die chipping. Generally speaking, a crack will extend to the inside of a die along a scribe lane. When the crack cracks into an effective circuit area of the die, it will lead to die failure and cause yield loss.

### SUMMARY

The present disclosure provides a semiconductor device, a manufacturing method thereof, and a memory system that can at least partially solve the above problems in the related art or other problems in the art.

Some examples of the present disclosure provide a semiconductor device comprising: a stacking structure comprising a memory array area and a first sealing area; and at least one circle of sealing structure in the first sealing area and surrounding the memory array area, wherein the scaling structure comprises a scaling ring body penetrating through the stacking structure and at least two circles of first dummy interconnection structures connected with the sealing ring body.

In some examples, the semiconductor device further comprises: a peripheral device structure comprising a device area provided with a peripheral device and a second sealing area; and at least two circles of second dummy interconnection structures in the second sealing area and respectively bonded and connected with the at least two circles of first dummy interconnection structures.

In some examples, the memory array area comprises a core area and a non-core area, the stacking structure comprises a plurality of dielectric layers and a plurality of gate layers alternately stacked in the core area and a first area of the non-core area, and the stacking structure comprises the plurality of dielectric layers and a plurality of gate sacrificial layers alternately stacked in a second area of the non-core area, wherein the semiconductor device further comprises: a plurality of contact structures in the second area, wherein the plurality of contact structures respectively extend to gate sacrificial layers of different layers, and each of the plurality of contact structures is connected with the gate layer of the same layer as the corresponding gate sacrificial layer in the core area through the gate layer of the same layer as the corresponding gate sacrificial layer in the first area; and a first interconnection structure in contact with the contact structure, and wherein the first interconnection structure is of the same material as the first dummy interconnection structure.

In some examples, the core area comprises a channel structure penetrating through the stacking structure, wherein the semiconductor device further comprises: a channel contact in contact with an end of the channel structure; and a second interconnection structure in contact with the channel contact, wherein the second interconnection structure is of the same material as the first interconnection structure and the first dummy interconnection structure.

In some examples, each of the contact structures comprises: a conductive plug in contact with the first interconnection structure; a first conductive portion in a layer of gate sacrificial layer in the second area and connected with the gate layer of the same layer as the layer of gate sacrificial layer in the core area through the gate layer of the same layer as the layer of gate sacrificial layer in the first area; and a second conductive portion in contact with the conductive plug and the first conductive portion and penetrating through the stacking structure of a corresponding number of layers.

In some examples, the conductive plug is of the same material as the channel contact.

In some examples, the contact structure further comprises: a first filling portion filled in a space enclosed by the conductive plug, the first conductive portion and the second conductive portion.

In some examples, the scaling ring body comprises: a metal layer penetrating through the stacking structure; and a metal plug in contact with the metal layer, wherein the metal plug is in the same layer and of the same material as the channel contact.

In some examples, the sealing ring body further comprises: a second filling portion filled in a space enclosed by the metal layer and the metal plug.

In some examples, the first dummy interconnection structure, the first interconnection structure and the second interconnection structure each comprise at least one layer of through-hole structure and at least one layer of interconnect line structure alternately arranged in a stacking direction, and the numbers of layers of the through-hole structures in the first dummy interconnection structure, the first interconnection structure and the second interconnection structure are the same, and the numbers of layers of the interconnection structure in the first dummy interconnection structure, the first interconnection structure and the second interconnection structure are the same.

Some other examples of the present disclosure provides a manufacturing method of a semiconductor device. The manufacturing method comprises: forming a stacking structure comprising a memory array area and a first sealing area; and forming at least one circle of sealing structure in the first sealing area of the stacking structure, wherein the at least one circle of sealing structure surrounds the memory array area, the sealing structure comprises a sealing ring body penetrating through the stacking structure and at least two circles of first dummy interconnection structures connected with the sealing ring body.

In some examples, the manufacturing method further comprises: forming a peripheral device in a device area of a peripheral device structure; forming, in a second sealing area of the peripheral device structure, second dummy interconnection structures matching positions and numbers of the first dummy interconnection structures; and bonding and connecting the first dummy interconnection structures and the second dummy interconnection structures.

In some examples, forming the stacking structure comprising the memory array area and the first sealing area comprises: forming an initial stacking structure comprising the memory array area and the first sealing area, wherein the initial stacking structure comprises a dielectric layer and a gate sacrificial layer sequentially stacked, and the memory array area comprises a core area and a non-core area; and replacing the gate sacrificial layer in the core area and the gate sacrificial layer in a first area in the non-core area in the initial stacking structure with a gate layer to form the stacking structure.

In some examples, forming at least one circle of sealing structure in the first sealing area of the stacking structure comprises: forming a plurality of contact structures in a second area of the non-core area and at least one circle of sealing ring body in the first sealing area in the same process, wherein the plurality of contact structures respectively extend to the gate sacrificial layers of different layers, and each of the plurality of contact structures is connected with the gate layer of the same layer as the corresponding gate sacrificial layer in the core area through a gate layer of the same layer as the corresponding gate sacrificial layer in the first area; and forming a plurality of first interconnection structures respectively in contact with the plurality of contact structures and the at least two circles of first dummy interconnection structures in the same process.

In some examples, wherein before replacing the gate sacrificial layer in the core area and the gate sacrificial layer in the first area in the non-core area in the initial stacking structure with the gate layer, forming the stacking structure comprising the memory array area and the first sealing area further comprises: forming a channel structure that is in the core area and penetrates through the initial stacking structure; wherein before forming the at least two circles of first dummy interconnection structures and the plurality of first interconnection structures in contact with the plurality of contact structures in the same process, the manufacturing method further comprises: forming a channel contact in contact with an end of the channel structure; wherein forming the at least two circles of first dummy interconnection structures and the plurality of first interconnection structures respectively in contact with the plurality of contact structures in the same process further comprises: forming a second interconnection structure in contact with the channel contact.

In some examples, forming the plurality of contact structures in the second area in the non-core area and the at least one circle of sealing ring body in the first sealing area in the same process comprises: forming at least one circle of contact groove in the first sealing area at the same time of forming a plurality of contact holes in the second area, wherein the plurality of contact holes respectively extend to a corresponding target gate sacrificial layer, the target gate sacrificial layer is one of a plurality of the gate sacrificial layers and the at least one circle of contact grooves surrounds the memory array area and penetrates through the stacking structure; removing a portion of the target gate sacrificial layer through each of the contact holes to form an epitaxial contact hole exposing the gate layer in the first area and corresponding to the target gate sacrificial layer; and forming the at least one circle of sealing ring body in the at least one circle of contact groove at the same time of forming the plurality of contact structures in the plurality of contact holes and the epitaxial contact holes.

In some examples, the contact structure comprises a first conductive portion, a second conductive portion and a conductive plug, and the sealing ring body comprises a metal layer and a metal plug; wherein forming the at least one circle of sealing ring body in the at least one circle of contact groove at the same time of forming the plurality of contact structures in the plurality of contact holes and the epitaxial contact holes comprises: forming the first conductive portion in the epitaxial contact hole, wherein the first conductive portion is in contact with the gate layer in the first area; forming a metal layer with an opening on a groove wall of the contact groove at the same time of forming the second conductive portion with an opening on a hole wall of the contact hole; and forming the metal plug closing the opening of the metal layer at the same time of forming the conductive plug closing the opening of the second conductive portion.

In some examples, before forming the metal plug closing the opening of the metal layer at the same time of forming the conductive plug that closes the opening of the second conductive portion and is in contact with the first conductive portion, the manufacturing method further comprises: filling an insulating material in the opening of the metal layer at the same time of filling an insulating material in the opening of the second conductive portion.

In some examples, wherein before forming the at least one circle of contact groove in the first scaling area at the same time of forming the plurality of contact holes in the second area in the non-core area, the manufacturing method further comprises: forming a first dielectric layer on a first side of the stacking structure; wherein before forming the metal plug closing the opening of the metal layer at the same time of forming the conductive plug closing the opening of the second conductive portion, the manufacturing method further comprises: forming an open hole penetrating through the first dielectric layer, wherein the open hole exposes an end of the channel structure; wherein forming the metal plug closing the opening of the metal layer at the same time of forming the conductive plug closing the opening of the second conductive portion further comprises: filling a metal material in the open hole to form the channel contact.

In some examples, wherein before forming the at least one circle of contact groove in the first sealing area at the same time of forming the plurality of contact holes in the second area in the non-core area, the manufacturing method further comprises: forming a first dielectric layer covering the stacking structure on a first side of the stacking structure; wherein forming the at least one circle of contact groove in the first sealing area at the same time of forming the plurality of contact holes in the second area in the non-core area further comprises: forming an open hole penetrating through the first dielectric layer, wherein the open hole exposes an end of the channel structure; wherein forming the metal plug closing the opening of the metal layer at the same time of forming the conductive plug closing the opening of the second conductive portion further comprises: filling a metal material in the open hole to form the channel contact.

In some examples, wherein forming the at least two circles of first dummy interconnection structures and the plurality of first interconnection structures respectively in contact with the plurality of contact structures in the same process and forming a second interconnection structure in contact with the channel contact comprises: forming a second dielectric layer covering the first dielectric layer on a first side of the stacking structure; and forming the at least two circles of first dummy interconnection structures, the plurality of first interconnection structures and the second interconnection structure penetrating through the second dielectric layer in the same process, wherein the first dummy interconnection structures, the first interconnection structures and the second interconnection structures are structures of a through-hole structure and an interconnection line alternately stacked.

Some other examples of the present disclosure provides a memory system. The memory system comprises: a three-dimensional memory comprising a semiconductor device according to any examples aforementioned; and a controller coupled with the three-dimensional memory and configured to control the three-dimensional memory.

According to at least one example of the present disclosure, the semiconductor device, its manufacturing method and a memory system provided by the present disclosure can, by arranging at least two circles of first dummy interconnection structures in the sealing structure surrounding the memory array area, prevent cracks from cracking into the memory array area of the semiconductor device, improve the protection ability and effect of the sealing structure, and reduce the risk of generating edge cracks in the die, and be conducive to improving the yield of products.

### BRIEF DESCRIPTION OF THE DRAWINGS

Other features, objects and advantages of the present disclosure will become more apparent by reading the detailed description of the non-limiting examples made with reference to the following accompanying drawings.

FIGS. 1A to 1D are schematic diagrams of sealing structures of semiconductor devices in some examples of the present disclosure.

FIG. 2A is a top view schematic diagram of a semiconductor device according to an example of the present disclosure.

FIG. 2B is a partially enlarged schematic diagram of area A shown in FIG. 2A according to the example of the present disclosure.

FIG. 2C is a schematic section view of a semiconductor device taken along the section lines I-I′ and II-II′ shown in FIG. 2A according to the example of the present disclosure.

FIG. 2D is a schematic section view of a channel structure according to an example of the present disclosure.

FIG. 3 is a schematic section view of a semiconductor device taken along the section lines I-I′ and II-II′ shown in FIG. 2A according to another example of the present disclosure.

FIG. 4A is a top view schematic diagram of a semiconductor device according to another example of the present disclosure.

FIG. 4B is a schematic section view of the semiconductor device shown in FIG. 4A according to the example of the present disclosure.

FIG. 5A is a top view schematic diagram of a semiconductor device according to another example of the present disclosure.

FIG. 5B is a schematic section view of a semiconductor device shown in FIG. 5A according to an example of the present disclosure.

FIG. 6 is a stress nephogram of the sealing structure in the semiconductor device shown in FIGS. 2A to 2C during the dicing operation.

FIG. 7A and FIG. 7B are stress nephograms of the sealing structures in the semiconductor devices shown in FIG. 1A and FIG. 1C during the dicing operation, respectively.

FIG. 8 is a schematic flowchart of a manufacturing method of a semiconductor device according to an example of the present disclosure.

FIGS. 9A to 9H are schematic process diagrams of a manufacturing method of a semiconductor device according to an example of the present disclosure.

FIG. 10 is a block diagram of a system having a memory system according to an example of the present disclosure.

FIG. 11A and FIG. 11B are schematic diagrams of a memory system according to an example of the present disclosure.

### DETAILED DESCRIPTION

To better understand the present disclosure, various aspects of the present disclosure will be described in more detail with reference to the accompanying drawings. These detailed descriptions are only a description of examples of the present disclosure and do not limit the scope of the present disclosure in any way. Throughout the description, the same reference numerals refer to the same elements. The expression “and/or” comprises any and all combinations of one or more of the associated listed items.

In this description, the expressions of the first, second, third, etc. are only used to distinguish one feature from another, and do not indicate any restriction on the features, and especially do not indicate order. Therefore, without departing from the teaching of the present disclosure, a first dummy interconnection structure discussed in the present disclosure can also be referred to as a second dummy interconnection structure, and vice versa.

In the accompanying drawings, the thickness, size and shape of the components have been slightly adjusted for ease of illustration. The accompanying drawings are examples only and are not drawn strictly to scale. As used herein, the terms “approximately,” “about” and the like are terms used to express approximation rather than degree, and are intended to explain the inherent deviation in the measured or calculated value that will be recognized by those skilled in the art.

Expressions such as “comprise,” “comprising,” “have,” “include” and/or “including” are open expressions rather than closed expressions in this description, which indicate the presence of at least one of the stated features, elements or components, but do not exclude the presence of at least one of one or more other features, elements, components or combinations thereof. Further, when a statement such as “at least one of . . . ” appears before a list of listed features, it modifies the entire list of features, rather than just individual elements in the list. In addition, when describing the examples of the present disclosure, “may” is used to mean “one or more examples of the present disclosure.” Moreover, the term “exemplary” is intended to refer to an example or illustration.

Unless otherwise defined, all terms used herein (comprising engineering terms and technical terms) have the same meaning as those generally understood by those skilled in the art to which the present disclosure belongs. Unless explicitly stated in the present disclosure, otherwise, words defined in common dictionaries should be interpreted as having the same meaning as their meaning in the context of the relevant technology, and should not be interpreted in an idealized or overly formal sense.

The examples and features in the examples in the present disclosure can be combined with each other without conflict. In addition, unless explicitly defined or contrary to the context, the operations contained in the method recited in the present disclosure need not be limited to the order recited, but can be executed in any order or in parallel.

In addition, when “connection” or “link” is used in this disclosure, it can indicate that the corresponding components are in direct contact or indirect contact, unless there are other explicit limitations or can be derived from the context. The present disclosure will be described in detail below with reference to the accompanying drawings and in combination with the examples.

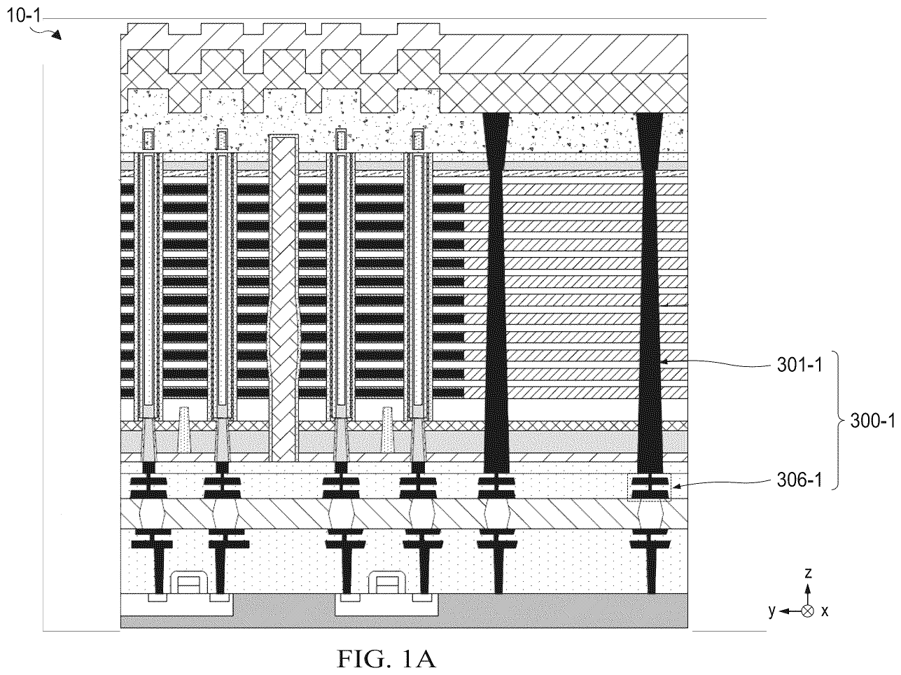

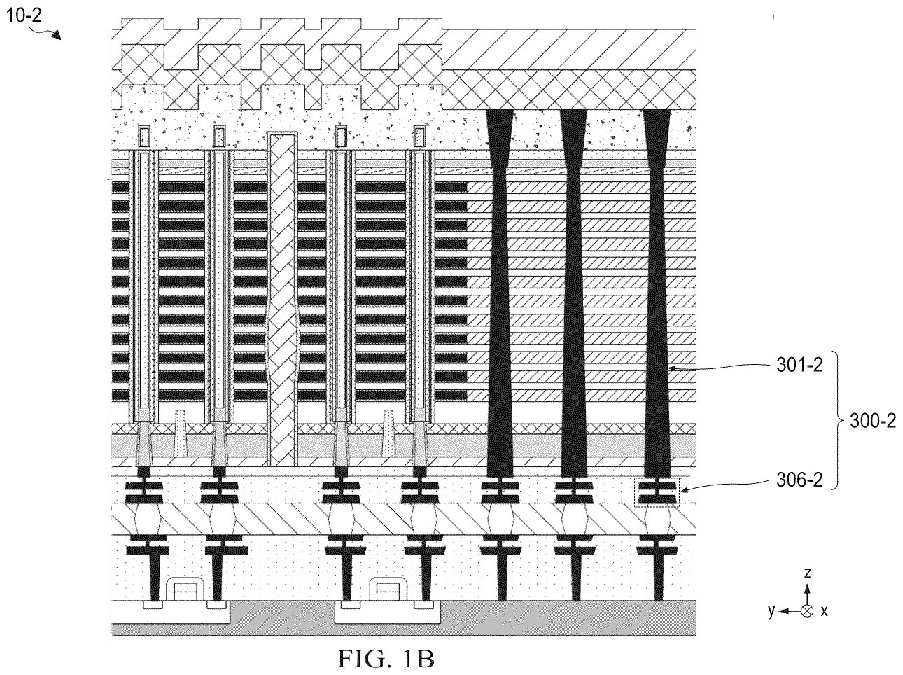

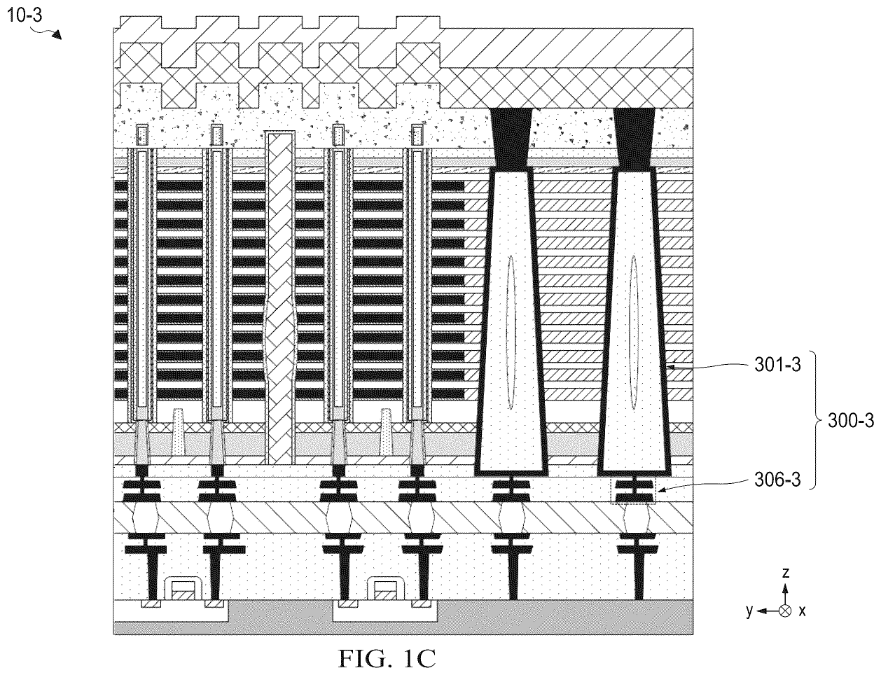

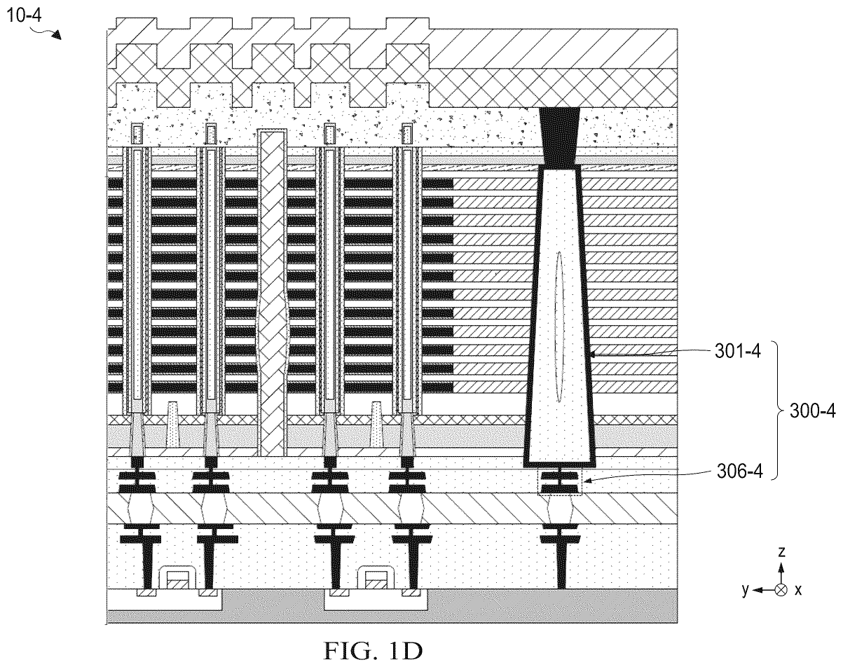

FIGS. 1A to 1D are schematic diagrams of sealing structures of semiconductor devices in some examples of the present disclosure. As shown in FIG. 1A, the semiconductor device 10-1 comprises two circles of sealing structures 300-1. Each circle of sealing structure 300-1 comprises a circle of sealing ring body 301-1 and a circle of first dummy interconnection structure 306-1. The scaling ring body 301-1 and the first dummy interconnection structure 306-1 are connected in the z direction. As shown in FIG. 1B, a difference from the semiconductor device 10-1 shown in FIG. 1A is that the semiconductor device 10-2 comprises three circles of sealing structures 300-2. As shown in FIG. 1C, a difference from the semiconductor device 10-1 shown in FIG. 1A is that an internal structure of the sealing ring body 301-3 is different. As shown in FIG. 1D, a difference from the semiconductor device 10-1 shown in FIG. 1A is that the semiconductor device 10-4 comprises a circle of sealing structure 300-4, and an internal structure of the sealing ring body 301-4 is different.

In the semiconductor devices 10-1 to 10-4 shown in FIGS. 1A to 1D, the sealing ring bodies 301-1 to 301-4 in the sealing structures 300-1 to 300-4 are each connected with a circle of first dummy interconnection structure 306-1 to 306-4. This sealing structure 300-1 to 300-4 has poor resistance to cracks, which may cause cracks to crack into an effective circuit area of the semiconductor devices 10-1 to 10-1 during dicing.

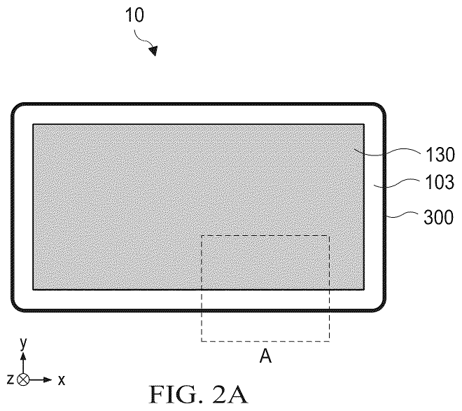

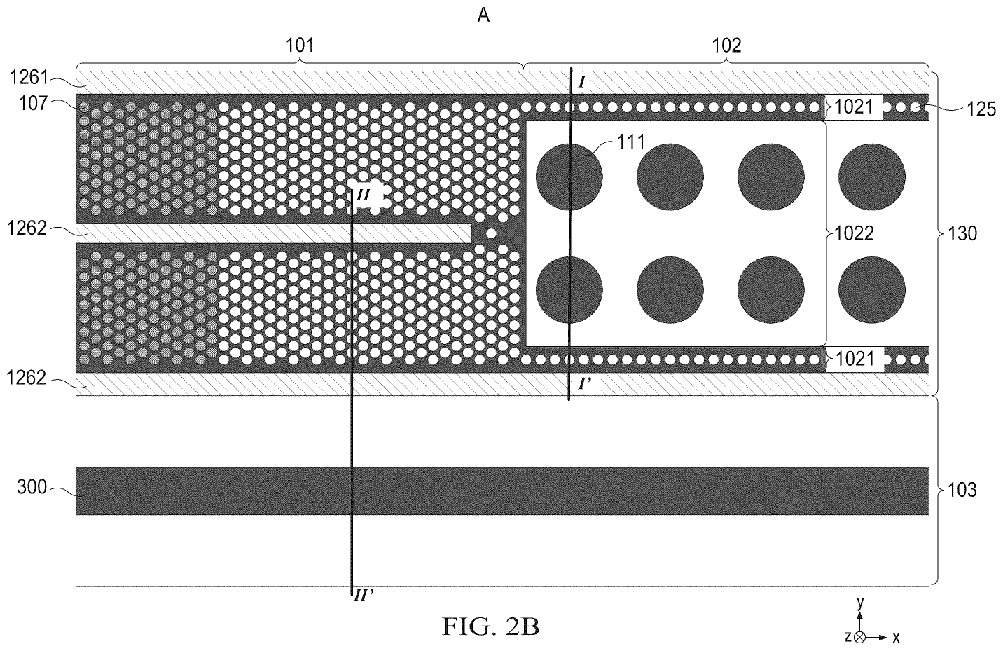

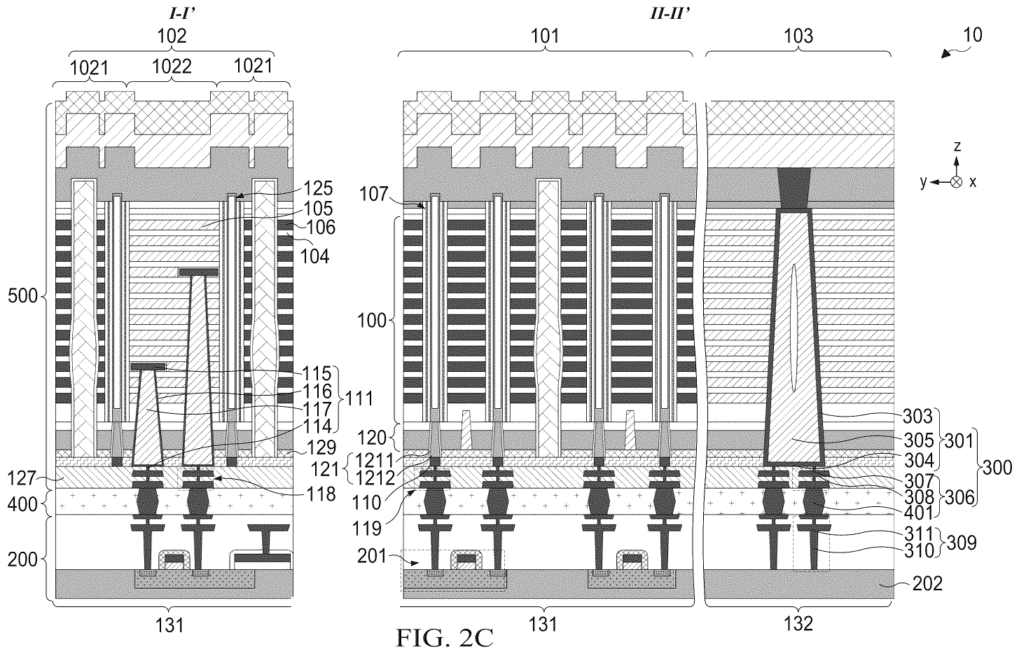

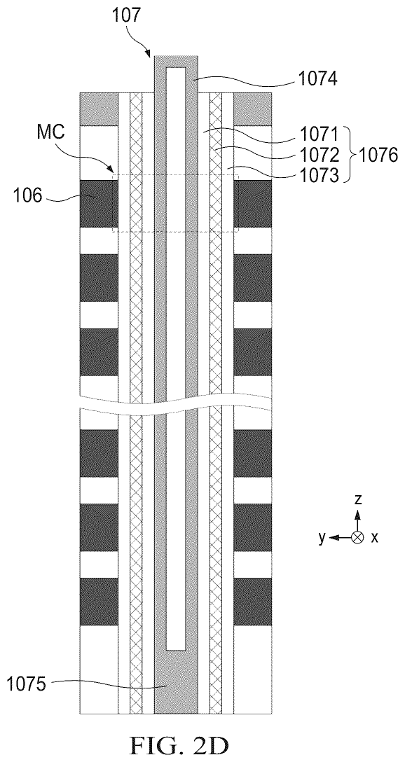

In view of this, some examples of the present disclosure provide a semiconductor device. For example, the semiconductor device may be a portion of a three-dimensional memory. FIG. 2A is a top view schematic diagram of a semiconductor device according to an example of the present disclosure. FIG. 2B is a partially enlarged schematic diagram of an area A shown in FIG. 2A according to the example of the present disclosure. FIG. 2C is a schematic section view of a semiconductor device taken along the section lines I-I′ and II-II′ shown in FIG. 2A according to the example of the present disclosure. In the following, the x direction, y direction and z direction in respective accompanying drawings show the spatial relationships of the respective components in the semiconductor device. For example, the z direction is a stacking direction of a stacking structure (or an initial stacking structure), and the x direction and y direction are two directions perpendicular to each other in a plane perpendicular to the stacking direction. For example, the x direction is a word line direction of the 3D memory, and the y direction is a bit line direction of the 3D memory. The same concept will be used throughout the present disclosure to describe the spatial relationships of the respective components in a semiconductor device.

As shown in FIGS. 2A to 2C, the semiconductor device 10 comprises a stacking structure 100 and a circle of sealing structure 300. The stacking structure 100 is divided into a memory array area 130 (e.g., a gray area shown in FIG. 2A) and a first sealing area 103 (e.g., a white area shown in FIG. 2A) in a plane perpendicular to the z direction, for example. The first sealing area 103 surrounds the memory array area 130. The sealing structure 300 is in the first sealing area 103 and surrounds the memory array area 130. The sealing structure 300 comprises a sealing ring body 301 and two circles of first dummy interconnection structures 306. The sealing ring body 301 penetrates through the stacking structure 100 and is connected with each circle of first dummy interconnection structure 306, for example, in the z direction. For example, the sealing ring body 301 and the first dummy interconnection structure 306 continuously surround the memory array area 130 in the first scaling area 103.

In some examples, the first dummy interconnection structure 306 comprises a first through-hole structure 307 and a first interconnection line structure 308. For example, the first through-hole structure 307 and the first interconnection line structure 308 continuously surround the memory array area 130 in the first sealing area 103. For example, the first through-hole structure 307 may extend longitudinally in the z direction, and the first interconnection line structure 308 may extend laterally in a plane perpendicular to the z direction. The first through-hole structure 307 and the first interconnection line structure 308 are alternately arranged in layers in the z direction. The present disclosure does not limit the number of layers of the first through-hole structure 307 and the first interconnection line structure 308. For example, the first dummy interconnection structure 306 comprises two layers of first through-hole structures 307 and two layers of first interconnection line structures 308 arranged alternately, and the first through-hole structure 307 is connected with the sealing ring body 301 in the z direction. The materials of the first through-hole structure 307 and the first interconnection line structure 308 may comprise, but are not limited to, tungsten, cobalt, copper, aluminum, polysilicon, titanium, titanium nitride or any other suitable conductive material.

In some examples, the sealing ring body 301 may comprise a metal layer 303 and a metal plug 304. The metal layer 303 may penetrate through the stacking structure 100. For example, the metal layer 303 may be an annular wall structure with an opening. The metal plug 304 is located at the opening and is in contact with the metal layer 303. In some examples, the scaling ring body 301 may further comprise a second filling portion 305. The second filling portion 305 can be filled in the space enclosed by the metal layer 303 and the metal plug 304. In some other examples, the space enclosed by the metal layer 303 and the metal plug 304 may remain unfilled. The materials of the metal layer 303 and the metal plug 304 may comprise, but are not limited to, tungsten, cobalt, copper, aluminum or any other suitable metal material. The material of the second filling portion 305 may comprise silicon oxide, silicon nitride, silicon oxynitride, or any other suitable insulating material. In some other examples, the sealing ring body can be made of only metal materials, which is not limited in the present disclosure. When the sealing ring body 301 comprises the metal layer 303 and the metal plug 304, it may be useful to optimize the stress distribution caused by the sealing ring body 301.

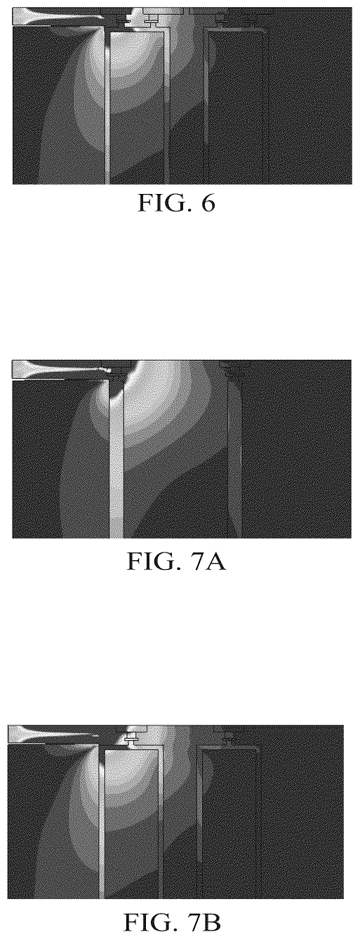

FIG. 6 is a stress nephogram of the sealing structures in the semiconductor devices shown in FIGS. 2A to 2C during the dicing operations. FIG. 7A and FIG. 7B are the stress nephograms of the sealing structures in the semiconductor devices shown in FIG. 1A and FIG. 1C in the dicing operation, respectively. As shown in FIG. 6, FIG. 7A and FIG. 7C, compared with the scaling structure with one circle of first dummy interconnection structure, the sealing structure with two circles of first dummy interconnection structures can reduce the crack risk coefficient of the semiconductor device. For example, the sealing structure with two circles of first dummy interconnection structures has a better blocking effect on the crack.

According to the example of the present disclosure, by providing two circles of first dummy interconnection structures in the sealing structure surrounding the memory array area, it can prevent cracks from cracking into the memory array area of a semiconductor device, improve the protection ability and effect of the sealing structure, reduce the risk of generating edge cracks in the die, and be conducive to improving the yield of products.

In some examples, as shown in FIG. 2C, the semiconductor device 10 may further comprise a peripheral device structure 200. For example, a portion of the semiconductor device 10 comprising the stacking structure 100 may be referred to as the memory array structure 500. The memory array structure 500 can be used to provide a memory cell array comprising a plurality of memory cells to realize data storage. The peripheral device structure 200 may be used to provide peripheral circuits that control the memory cell array to implement various operations such as writing, reading, erasing, and the like. The memory array structure 500 and the peripheral device structure 200 may be bonded and connected in the z direction. For example, the memory array structure 500 and the peripheral device structure 200 may be bonded and connected in the z direction through the bonding layer 400. For example, the bonding layer 400 may comprise a plurality of bonding contacts 401. A portion of the bonding layer 400 other than the bonding contact 401 may be made of an insulating material. A material for bonding the contact 401 may comprise, but are not limited to, tungsten, cobalt, copper, aluminum, titanium nitride, polysilicon or any other suitable conductive material. It should be noted that the bonding referred to in this disclosure can be any appropriate bonding technology, such as hybrid bonding, anodic bonding, melt bonding, transfer bonding, adhesive bonding, eutectic bonding, etc.

In some examples, the peripheral device structure 200 may be divided into a device area 131 and a second sealing area 131 in a plane perpendicular to the z direction. The second sealing area 131 surrounds the device area 131. For example, in a projection plane perpendicular to the z direction, the first sealing area 103 and the second sealing area 131 overlap, and the memory array area 130 and the device area 131 overlap.

In some examples, the peripheral device structure 200 may comprise a second substrate 202 and a plurality of peripheral devices 201. Within the device area 131, a plurality of peripheral devices 201 may be located on one side of the second substrate 202. The types of peripheral devices 201 may comprise metal oxide semiconductor field effect transistor (MOSFET), fin field effect transistor (FinFET), bipolar transistor (BJT), diode, resistor, inductor, capacitor, or any other suitable semiconductor device. Several peripheral devices 201 may constitute at least one of digital, analog, or mixed digital analog functional circuits for realizing various functions. These functional circuits may, for example, control the memory cell array through at least one of word lines or bit lines to achieve various operations such as writing, reading, erasing, and the like. The functional circuits may comprise, but are not limited to, a page buffer/sense amplifier, a decoder (e.g., a row decoder or a column decoder), a word line driver, an input/output (I/O) circuit, a charge pump, a voltage source or a voltage generator, a current or voltage reference, etc.

In some examples, the peripheral device structure 200 may further comprise two circles of second dummy interconnection structures 309. The second dummy interconnection structure 309 is located in the second sealing area 131. For example, the second dummy interconnection structure 309 continuously surrounds the device area 131 in the second sealing area 131. The number of circles of the first dummy interconnection structures 306 may be the same as the total number of circles of the second dummy interconnection structures 309. Each circle of first dummy interconnection structure 306 and each circle of second dummy interconnection structure 309 are bonded and connected, for example, through the bonding contact 401 of the bonding layer 400. In this example, when the semiconductor device 10 comprises the peripheral device structure 200, by providing the second dummy interconnection structure 309 in the second sealing area 131 and bonding and connecting it with the first dummy interconnection structure 306, the second dummy interconnection structure 309 and the sealing structure 300 can be used as a whole structure to prevent cracks from cracking into the memory array area 130 and the device area 131 of the semiconductor device 10, reduce the risk of generating edge cracks in the die, and be conducive to improving the yield of products.

In some examples, the second dummy interconnection structure 309 is similar to the first dummy interconnection structure 307, and the second dummy interconnection structure 309 may comprise a second through-hole structure 310 and a second interconnection line structure 311. For example, the second through-hole structure 310 and the second interconnection line structure 311 continuously surround the device area 131 in the second sealing area 131. The second through-hole structure 310 and the second interconnection line structure 311 are alternately arranged in layers in the z direction. The number of layers of the first through-hole structure 307 and the second through-hole structure 310 may be the same or different, and the number of layers of the first interconnection line structure 308 and the second interconnection line structure 311 may be the same or different, which is not limited in this disclosure.

In some examples, as shown in FIG. 2B, the memory array area 130 may comprise a core area 101 and a non-core area 102 arranged along the x direction. In some examples, the two core areas may be located on two sides of the non-core area in the x direction (not shown). In some other examples, two non-core areas may be located on two sides of the core area in the x direction (not shown). In some examples, the non-core area 102 may comprise a first area 1021 and a second area 1022 arranged along the y direction. For example, the two first areas 1021 are located on two sides of the second area 1022 in the y direction.

In some examples, as shown in FIG. 2C, a portion of the stacking structure 100 located in the core area 101 and the first area 1021 of the non-core area 102 may comprise a plurality of dielectric layers 104 and a plurality of gate layers 106 alternately stacked in the z direction. The gate layer 106 may serve as a word line of a three-dimensional memory. A portion of the stacking structure 100 located in the second area 1022 of the non-core area 102 and the first sealing area 103 may comprise a plurality of dielectric layers 104 and a plurality of gate sacrificial layers 105 alternately stacked in the z direction. The materials of the dielectric layer 104 and the gate sacrificial layer 105 may have different etching selection ratios with respective to the same etchant. For example, the material of the dielectric layer 104 may comprise silicon oxide, and the material of the gate sacrificial layer 105 may comprise silicon nitride. For example, the plurality of gate layers 106 may correspond to the plurality of gate sacrificial layers 105 one by one in the z direction. The present disclosure does not specifically limit the number of stacked layers of the dielectric layer 104 and the gate layer 106 (or the gate sacrificial layer 105). The more the number of stacked layers of the dielectric layer 104 and the gate layer 106 (or the gate sacrificial layer 105), the higher the integration degree of the memory cells, for example, the greater the unit storage density.

In some examples, the gate layer 106 may comprise a conductive material. The conductive material may comprise, but is not limited to, metals (e.g., tungsten, cobalt, copper, aluminum), polysilicon, or any other suitable conductive material. For example, the material of the gate layer 106 is tungsten. In some other examples, the gate layer 106 may comprise a high dielectric constant layer, an adhesive layer, and a conductive layer (not shown) sequentially arranged from outside to inside. The materials of the high dielectric constant layer may comprise, but are not limited to, alumina, zirconia, hafnium oxide or any other suitable high dielectric constant materials. The materials of the adhesive layer may comprise, but are not limited to, titanium, titanium nitride, tantalum, tantalum nitride or any other suitable material. It should be noted that respective portions of the gate layer 105 located in different areas may have different internal structures, which is not limited in the present disclosure.

In some examples, as shown in FIG. 2C, the semiconductor device 10 may further comprise a channel structure 107. For example, a plurality of channel structures 107 are arranged in array in the core area 101. The channel structure 107 may penetrate through the stacking structure 100. FIG. 2D is a schematic section view of a channel structure according to an example of the present disclosure. In some examples, as shown in FIG. 2D, the channel structure 107 may comprise a barrier layer 1071, a charge capture layer 1072, a tunneling layer 1073, and a channel layer 1074 sequentially arranged from outside to inside. The barrier layer 1071, the charge capture layer 1072, and the tunneling layer 1073 may be referred to as a functional layer 1076. For example, the materials of the barrier layer 1071, the charge capture layer 1072, and the tunneling layer 1073 may sequentially comprise silicon oxide, silicon nitride, and silicon oxide. The material of the channel layer 1074 may comprise any other suitable semiconductor material such as silicon (e.g., amorphous silicon, polycrystalline silicon, or monocrystalline silicon).

In some examples, a portion of the channel structure 107 surrounded by one gate layer 106 and a portion of the gate layer 106 constitute one memory cell MC. A plurality of memory cells MC are arranged in series along an extension direction (e.g., the z direction) of the channel structure 107 to form a memory string and share the channel layer 1074. The rest of the gate layer 106 can be used as a word line connecting multiple memory cells MC of the same height in different memory strings. For example, by applying a voltage to the gate layer 106, the memory cell MC can make the charge in the channel layer 1074 enter the charge capture layer 1072, or return the charge in the charge capture layer 1072 to the channel layer 1074, so that the memory cell MC is in a programmed state or an erased state (unprogrammed state).

In some examples, as shown in FIG. 2C, the semiconductor device 10 may further comprise a dummy channel structure 125. For example, a plurality of dummy channel structures 125 are arranged in the first area 1021 of the non-core area 102. The dummy channel structure 125 may penetrate through the stacking structure 100. In some examples, the dummy channel structure 125 may have the same internal structure as the channel structure 107. In another example, the dummy channel structure 125 may comprise an insulating material. For example, dummy channel structure 125 may be used to provide mechanical support and/or load balancing.

In some examples, the semiconductor device 10 may further comprise a selection stacking structure 120 and a selection channel structure 121. For example, the selection stacking structure 120 may be located between the stacking structure 100 and the first dummy interconnection structure 306. The selection stacking structure 120 may comprise alternately stacked selection dielectric layers and selection gate layers in the z direction. For example, the number of selection gate layers may be 1 to 5. The material of the selection dielectric layer may comprise, but are not limited to, silicon oxide, silicon nitride, silicon oxynitride or any other suitable insulating material. The material of the selection gate layer may comprise, but is not limited to, metals (e.g., tungsten, cobalt, copper, aluminum), polysilicon, or any other suitable conductive material. For example, the material of the selection gate layer is polysilicon. Alternatively, the semiconductor device 10 may further comprise a stop layer 129 located on a side of the selection stacking structure 120 away from the stacking structure 100. For example, the material of the stop layer 129 may comprise silicon nitride.

In some examples, the selection channel structure 121 may, for example, penetrate through the stop layer 129 and the selection stacking structure 120 to the channel structure 107. For example, the selection channel structure 121 may comprise a gate insulation layer 1211 and a selection channel layer 1212 sequentially arranged from outside to inside. The selection channel layer 1212 is in contact with, for example, the channel plug 1075 in the channel structure 107 (refer to FIG. 2D), so that the selection channel structure 121 and the channel structure 107 are connected in the z direction. The selection gate layers in the selection channel structure 121 and the selection stacking structure 120 may be used to constitute a selection transistor. A plurality of selection channel structures 121 correspond to a plurality of channel structures 107 one by one. Alternatively, a plurality of selection channel structures 121 correspond to a plurality of dummy channel structures 125 one by one.

In some examples, the semiconductor device 10 may further comprise a contact structure 111. For example, a plurality of contact structures 111 are arranged in the second area 1022 of the non-core area 102, for example. As described above, the portion of the stacking structure 100 located in the second area 1022 of the non-core area 102 may comprise a plurality of dielectric layers 104 and a plurality of gate sacrificial layers 105 alternately stacked in the z direction. For example, a plurality of contact structures 111 extend from a side of the stacking structure 100 close to the peripheral device structure 200 into the gate sacrificial layers 105 of different layers, and are connected with the gate layer 106 of the same layer as the corresponding gate sacrificial layer 105 located in the core area 101 through the gate layer 106 of the same layer as the corresponding gate sacrificial layer 105 located in the first area 1021, so that the plurality of gate layers 106 can be led out.

In some examples, the contact structure 111 may comprise a conductive plug 114, a first conductive portion 115, and a second conductive portion 116. The first conductive portion 115 is located in a layer of gate sacrificial layer 105 of the second area 1022, and is connected to the gate layer 106 of the same layer as the layer of gate sacrificial layer 105 located in the core area 101 through the gate layer 106 of the same layer as the layer of gate sacrificial layer 105 located in the first area 1021. The second conductive portion 116 penetrates through the stacking structure 100 of the corresponding number of layers and is in contact with the first conductive portion 115. For example, the first conductive portion 115 extends laterally in a plane perpendicular to the z direction. The second conductive portion 116 extends longitudinally in the z direction, and the second conductive portion 116 is, for example, a cylindrical structure with an opening. The conductive plug 114 is located at an end of the second conductive portion 116 away from the first conductive portion 115 and is in contact with the second conductive portion 116. In some examples, the contact structure 111 may further comprise a first filling portion 117. The first filling portion 117 may be filled in the space enclosed by the conductive plug 114, the first conductive portion 115 and the second conductive portion 116. In some other examples, the space enclosed by the conductive plug 114, the first conductive portion 115 and the second conductive portion 116 may remain unfilled. The materials of the conductive plug 114, the first conductive portion 115, and the second conductive portion 116 may comprise, but are not limited to, tungsten, cobalt, copper, aluminum, polysilicon, titanium, titanium nitride, or any other suitable conductive material. The material of the first filling portion 117 may comprise silicon oxide, silicon nitride, silicon oxynitride or any other suitable insulating material. In some other examples, the contact structure may comprise only conductive materials, which is not limited in the present disclosure. When the contact structure 111 comprises the first conductive portion 115, the second conductive portion 116, the first filling portion 117 and the conductive plug 114, it is beneficial to optimize the stress distribution caused by the contact structure 111.

In some examples, the semiconductor device 10 may further comprise a channel contact 110. When the semiconductor device 10 comprises the selection channel structure 121, the channel contact 110 may contact an end of the selection channel structure 121. When the semiconductor device 10 does not comprise the selection channel structure 121, the channel contact 110 may contact an end of the channel structure 107 (e.g., the channel plug 1075 shown in FIG. 2D). In some examples, any two of the channel contact 110, the conductive plug 114 in the contact structure 111 and the metal plug 304 in the sealing ring body 301 can be in the same layer and have the same material. The “same layer” in this disclosure means that at least one surface perpendicular to the z direction in the component is approximately flush. For example, the surfaces of the channel contact 110, the conductive plug 114 and the metal plug 304 near the peripheral device structure 200 are flush approximately.

In some examples, the semiconductor device 10 may further comprise a first interconnection structure 118 and a second interconnection structure 119. The first interconnection structure 118 may be in contact with the conductive plug 114 in the contact structure 111. The second interconnection structure 119 may be in contact with the channel contact 110. In some examples, the first interconnection structure 118 and the second interconnection structure 119 are similar to the first dummy interconnection structure 306, and both the first interconnection structure 118 and the second interconnection structure 119 can comprise a through-hole structure and an interconnection line structure. The through-hole structure and the interconnect line structure can be alternately arranged in layers in the z direction. The through-hole structure and the interconnection line structure in any two of the first dummy interconnection structure 306, the first interconnection structure 118 and the second interconnection structure 119 have the same number of layers and the same material.

In some examples, the first interconnection structure 118, the second interconnection structure 119, and the first dummy interconnection structure 306 are located in the second dielectric layer 127. The second dielectric layer 127 may also be referred to as an interlayer dielectric layer to electrically isolate the first interconnection structure 118, the second interconnection structure 119, and the first dummy interconnection structure 306 from each other. The material of the second dielectric layer 127 may comprise, but is not limited to, silicon oxide, silicon nitride, silicon oxynitride, or any other suitable insulating material.

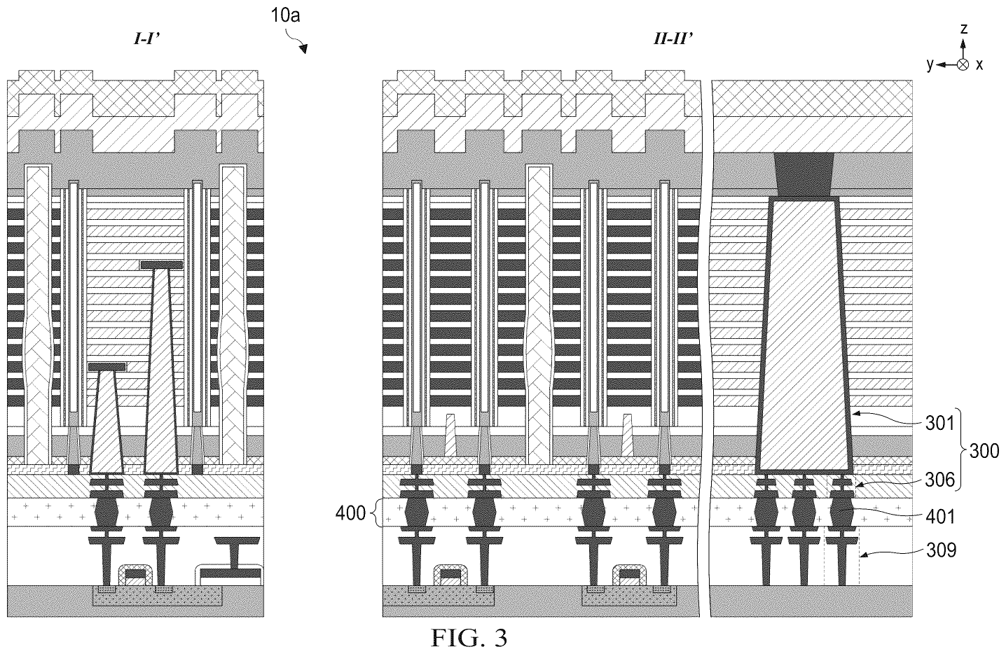

FIG. 3 is a schematic section view of the semiconductor device 10a taken along the section lines I-I′ and II-II′ shown in FIG. 2A according to another example of the present disclosure. For the purpose of brevity, the components in the following examples that are the same as those in the semiconductor device 10 will not be repeated in this disclosure.

As shown in FIG. 3, different from the semiconductor device 10 shown in FIGS. 1A to 2D, the semiconductor device 10a comprises a circle of sealing structure 300. The sealing structure 300 comprises a circle of sealing ring body 301 and three circles of first dummy interconnection structures 306. The sealing ring body 301 is connected with each circle of first dummy interconnection structure 306, for example, in the z direction. The number of circles of the second dummy interconnection structures 309 is the same as the total number of circles of the first dummy interconnection structures 306, for example, three circles. Each circle of first dummy interconnection structure 306 and each circle of second dummy interconnection structure 309 are bonded and connected, for example, through the bonding contact 401 of the bonding layer 400.

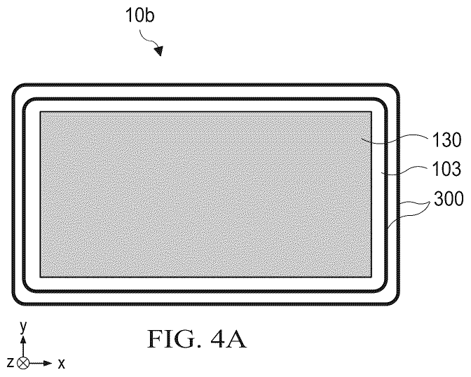

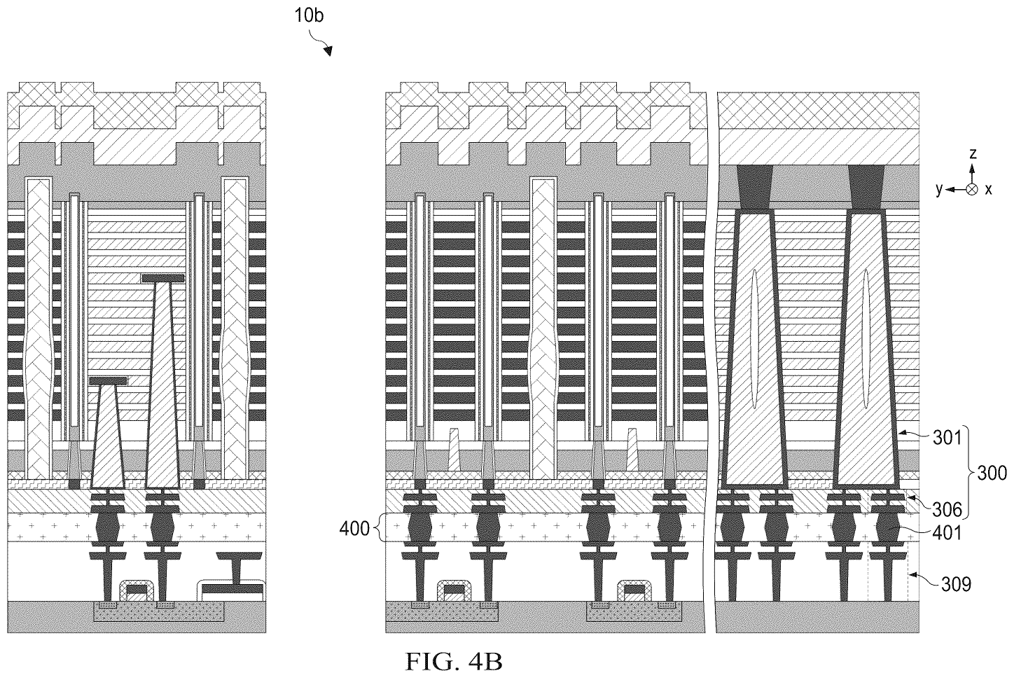

FIG. 4A is a top view schematic diagram of a semiconductor device according to another example of the present disclosure. FIG. 4B is a schematic section view of the semiconductor device shown in FIG. 4A according to the example of the present disclosure.

As shown in FIG. 4A and FIG. 4B, different from the semiconductor device 10 shown in FIGS. 2A to 2D, the semiconductor device 10b comprises two circles of sealing structures 300. Each circle of sealing structure 300 comprises one circle of sealing ring body 301 and two circles of first dummy interconnection structures 306. The number of circles of the second dummy interconnection structures 309 is the same as the total number of circles of the first dummy interconnection structures 306, for example, four circles. Each circle of first dummy interconnection structure 306 and each circle of second dummy interconnection structure 309 are bonded and connected, for example, through the bonding contact 401 of the bonding layer 400.

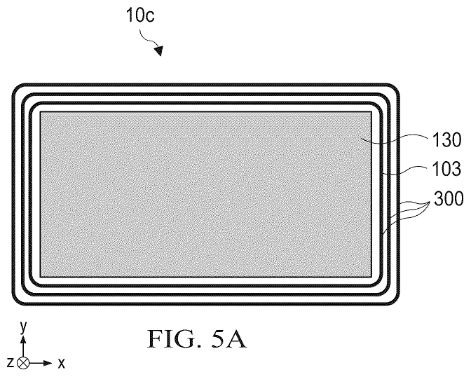

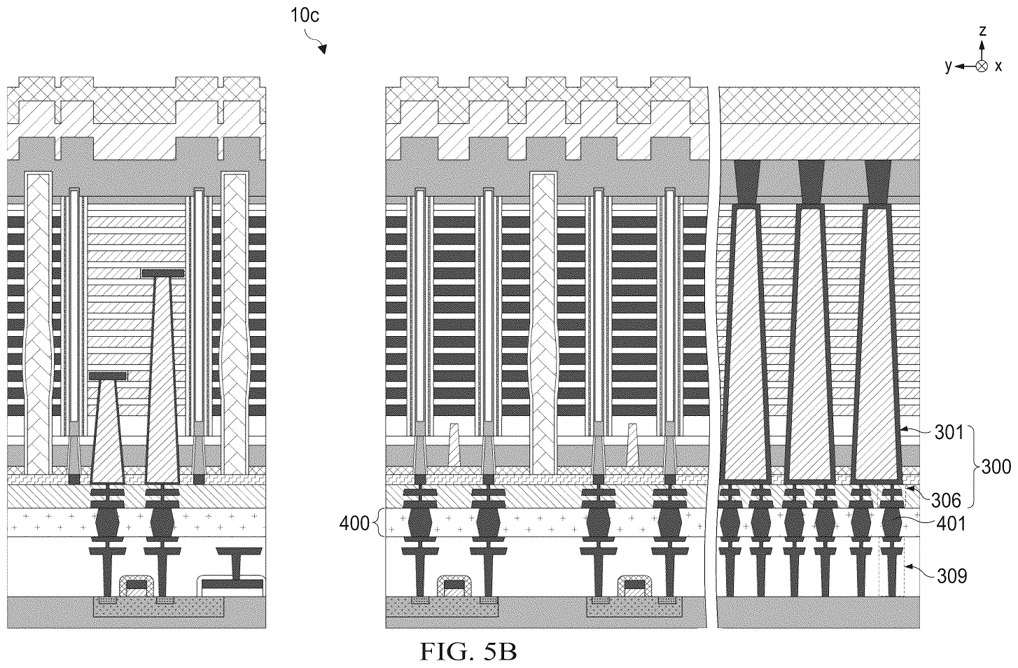

FIG. 5A is a top view schematic diagram of a semiconductor device according to another example of the present disclosure. FIG. 5B is a schematic section view of a semiconductor device shown in FIG. 5A according to an example of the present disclosure.

As shown in FIG. 5A and FIG. 5B, different from the semiconductor device 10 shown in FIGS. 2A to 2D, the semiconductor device 10c comprises three circles of sealing structures 300. Each circle of sealing structure 300 comprises one circle of sealing ring body 301 and two circles of first dummy interconnection structures 306. The number of circles of the second dummy interconnection structures 309 is the same as the total number of circles of the first dummy interconnection structures 306, for example, six circles. Each circle of first dummy interconnection structure 306 and each circle of second dummy interconnection structure 309 are bonded and connected, for example, through the bonding contact 401 of the bonding layer 400.

It should be noted that, without violating the teaching of the present disclosure, the semiconductor device may comprise at least one circle of sealing structure, and the sealing structure may comprise at least two circles of first dummy interconnection structures. By providing at least two circles of first dummy interconnection structures in the sealing structure surrounding the memory array area, it can prevent cracks from cracking into the memory array area of the semiconductor device, improve the protection ability and effect of the sealing structure, reduce the risk of generating edge cracks in the die, and be conducive to improving the product yield advantageously.

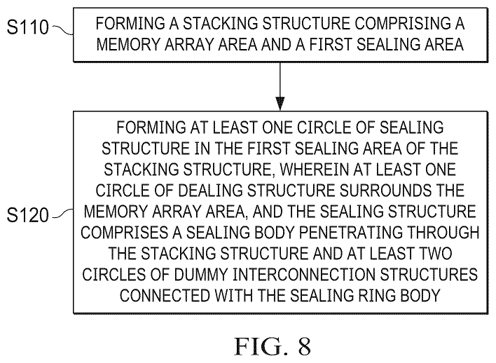

Some examples of the present disclosure provide a manufacturing method of a semiconductor device. FIG. 8 is a schematic flowchart of a manufacturing method of a semiconductor device according to an example of the present disclosure. As shown in FIG. 8, the manufacturing method 1000 of the semiconductor device (hereinafter referred to as the manufacturing method 1000) comprises operations S110 and S120.

S110: forming a stacking structure comprising a memory array area and a first sealing area.

S120: forming at least one circle of sealing structure in the first sealing area of the stacking structure, wherein at least one circle of sealing structure surrounds the memory array area, and the sealing structure comprises a sealing ring body penetrating through the stacking structure and at least two circles of first dummy interconnection structures connected with the sealing ring body.

According to the manufacturing method of the semiconductor device provided by the example, by forming at least two circles of first dummy interconnection structures in the sealing structure surrounding the memory array area, it can prevent cracks from cracking into the memory array area of the semiconductor device, improve the protection ability and effect of the scaling structure, reduce the risk of generating edge cracks in the die, and be conducive to improving the yield of the product.

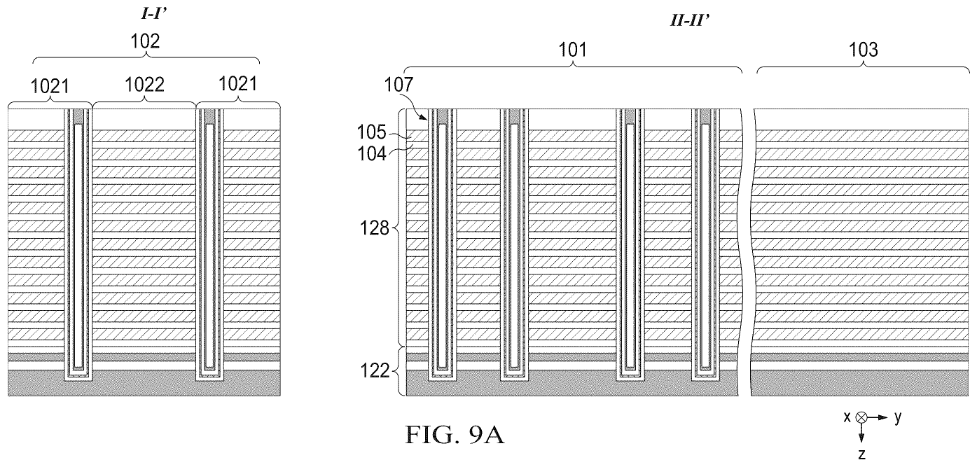

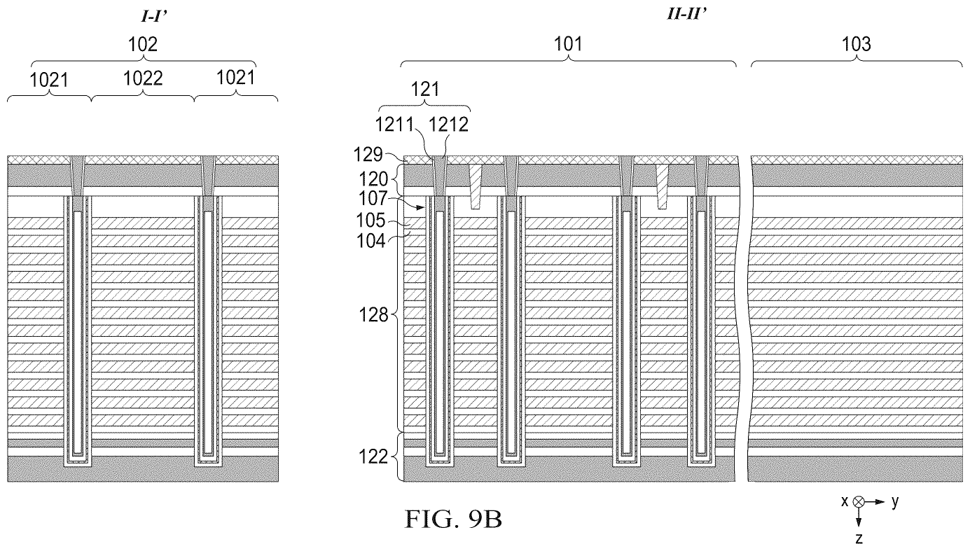

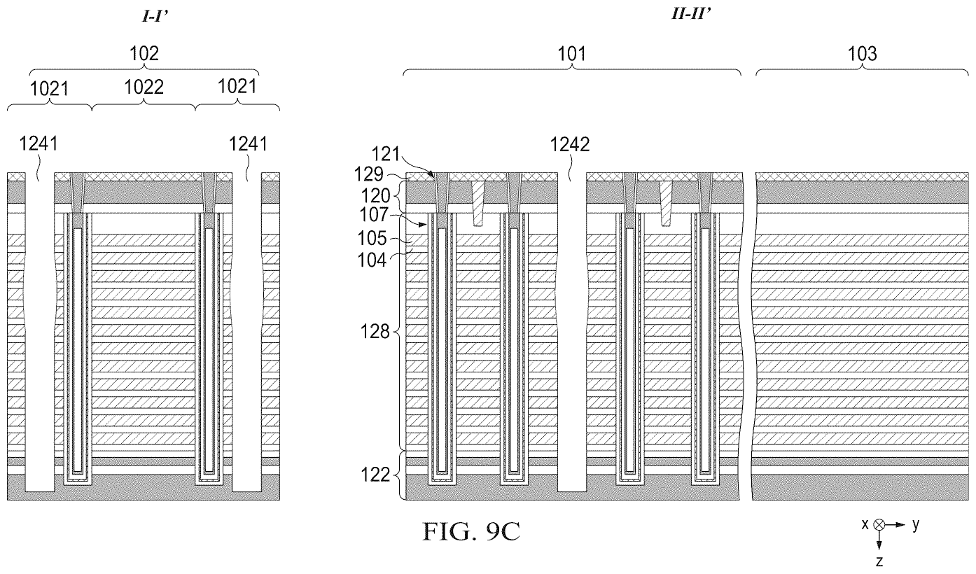

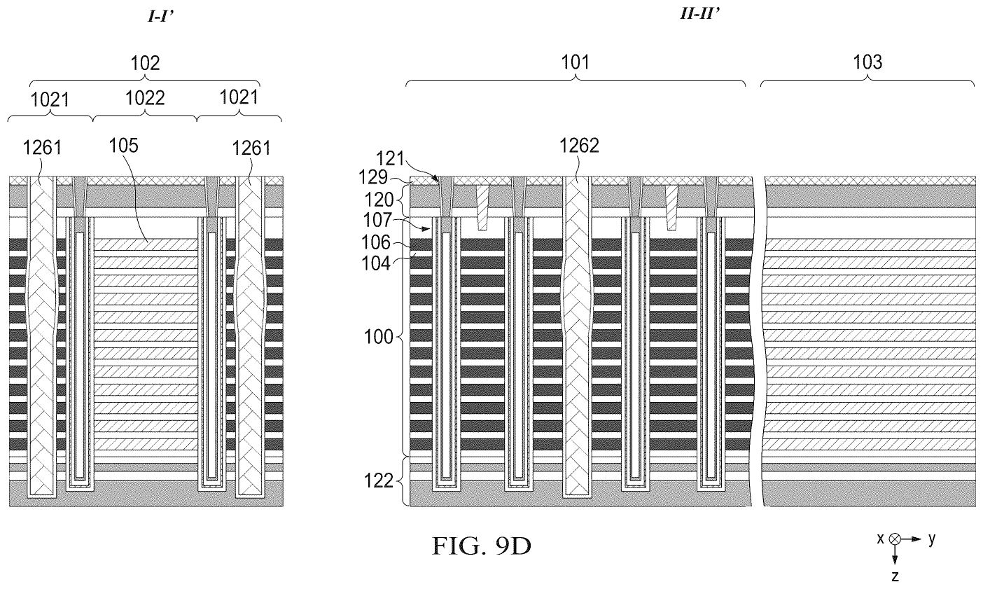

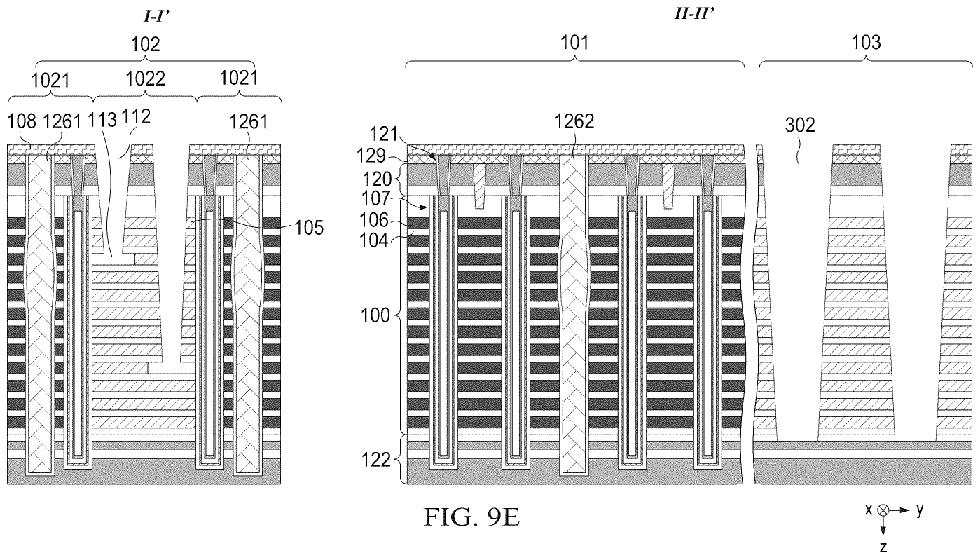

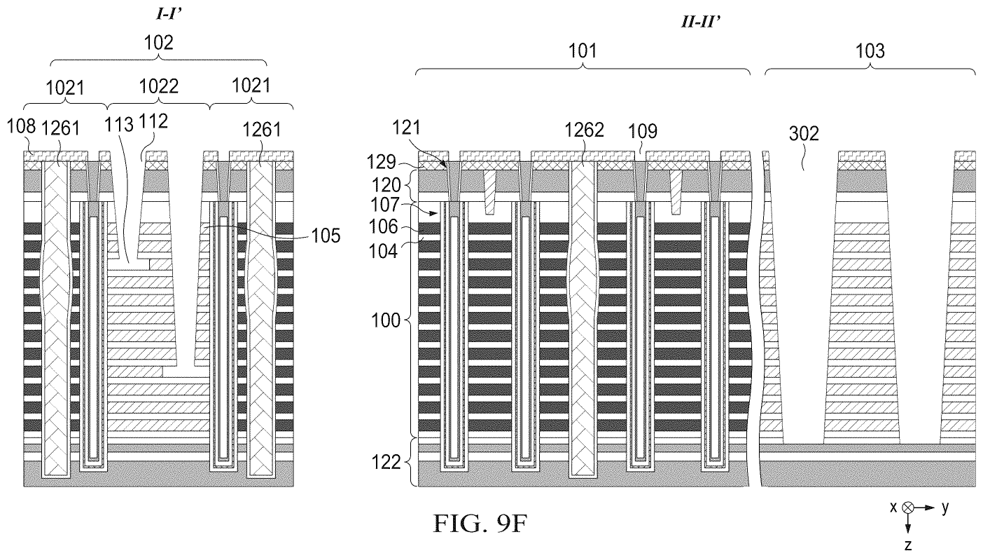

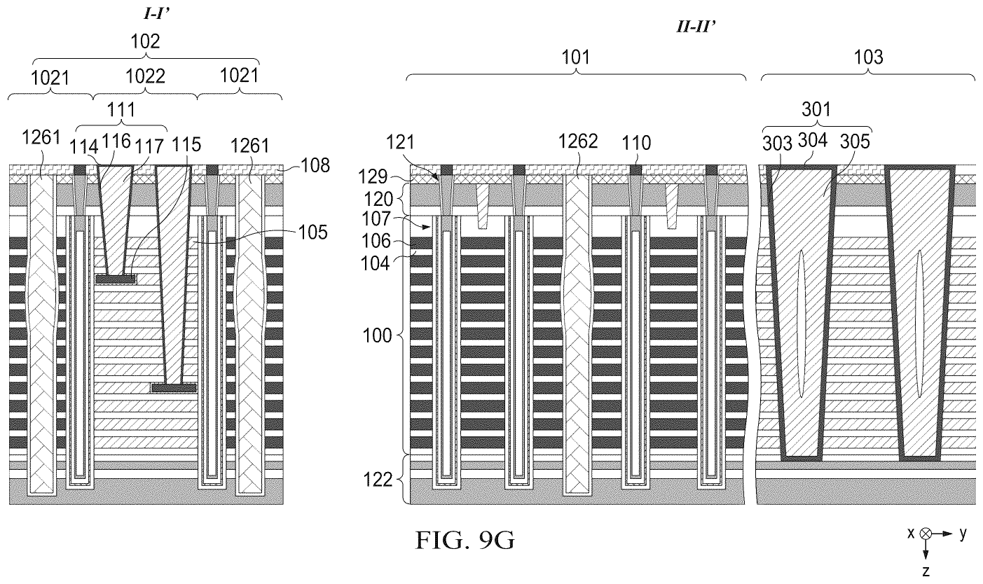

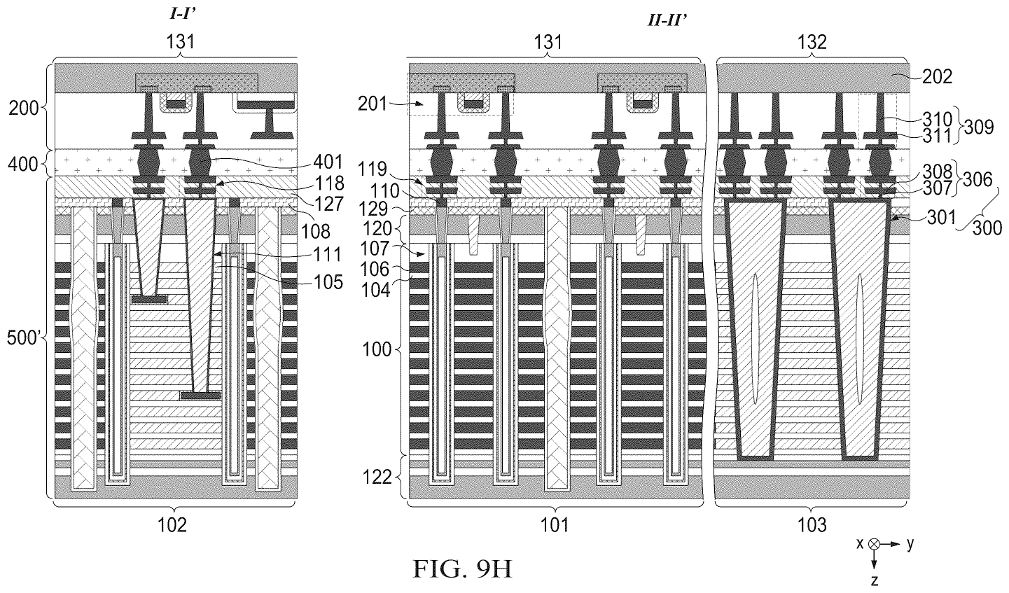

FIGS. 9A to 9H are process schematic diagrams of a manufacturing method of a semiconductor device according to an example of the present disclosure. For example, the manufacturing method 1000 shown in FIG. 8 may form the semiconductor device 10b shown in FIGS. 4A and 4B. The operations S110 and S120 described above will be illustratively described below in connection with FIGS. 9A to 9H and FIGS. 4A to 4B.

S110: forming a stacking structure comprising a memory array area and a first sealing area.

In operation S110, as shown in FIG. 9A, the initial stacking structure 128 may be formed at a side of the first substrate 122. The material of the first substrate 122 may comprise, but is not limited to, silicon (e.g., monocrystalline silicon c-Si), silicon germanium (SiGe), gallium arsenide (GaAs), germanium (GE), silicon on insulator (SOI), or any other suitable material. For example, the first substrate 122 may be a composite substrate having a multilayer structure. Referring to FIG. 4A, the initial stacking structure 128 is divided into a memory array area 130 and a first sealing area 103 in a plane perpendicular to the z direction. The first sealing area 103 surrounds the memory array area 130.

In some examples, the portions of the initial stacking structure 128 located in the memory array area 130 and the first sealing area 103 both comprise a plurality of dielectric layers 104 and a plurality of gate sacrificial layers 105 alternately stacked in the z direction. For example, the dielectric layer 104 and the gate sacrificial layer 105 may be formed by a thin film deposition process such as physical vapor deposition (PVD), chemical vapor deposition (CVD), atomic layer deposition (ALD), or any combination thereof.

In some examples, as shown in FIG. 9A, the manufacturing method 1000 may comprise the operation of forming the channel structure 107. For example, a channel hole (roughly corresponding to the outer contour of the channel structure 107) penetrating through the initial stacking structure 128 and extending into the first substrate 122 may be formed first. Then, referring to FIG. 2D, a barrier layer 1071, a charge capture layer 1072, a tunneling layer 1073, and a channel layer 1074 may be sequentially formed on the inner wall of the channel hole by a thin film deposition process such as PVD, CVD, ALD, or any combination thereof, and a channel plug 1075 may be formed at the end of the channel hole to form a channel structure 107.

In some examples, as shown in FIG. 9B, the manufacturing method 1000 may further comprise the operations of forming the selection stacking structure 120 and the selection channel structure 121. For example, first, the selection stacking structure 120 may be formed on a side of the initial stacking structure 128 away from the first substrate 122 (hereinafter referred to as the first side) by a thin film deposition process such as PVD, CVD, ALD or any combination thereof. Alternatively, a stop layer 129 may be formed on a side of the selection stacking structure 120 away from the initial stacking structure 128 by a thin film deposition process such as a PVD, CVD, ALD or any combination thereof. Then, a selection channel hole (roughly corresponding to the outer contour of the selection channel structure 121), for example, penetrating through the stop layer 129 and the selection stacking structure 120 may be formed to the channel structure 107 using a photolithography and etching process. Then, the gate insulating layer 1211 and the selection channel layer 1212 can be formed on the inner wall of the selection channel hole by a thin film deposition process such as PVD, CVD, ALD or any combination thereof, to form the selection channel structure 121. The selection channel layer 1212 contacts the channel plug 1075 in the channel structure 107 (refer to FIG. 2D).

In some examples, as shown in FIG. 9C, the first gate line slit 1241 and the second gate line slit 1242 may be formed using photolithography and etching processes. Referring to FIG. 2B, the first gate line slit 1241 and the second gate line slit 1242 may be grooves of the first gate line slit structure 1261 and the second gate line slit structure 1262 being in an unfilled state, respectively. The memory array area 130 may comprise a core area 101 and a non-core area 102 arranged in the x direction. The non-core area 102 may comprise a first area 1021 and a second area 1022 arranged in the y direction. For example, two first areas 1021 are located on two sides of the second area 1022 in the y direction. The first gate line slit 1241 may extend continuously along the x direction in the core area 101 and the non-core area 102, and the second gate line slit 1242 may extend intermittently along the x direction in the core area 101. The second gate line slit 1242 may be located between two adjacent first gate line slits 1241. In other words, the first gate line slit 1241 and the second gate line slit 1242 may be arranged along the y direction. As shown in FIG. 9C, the first gate line slit 1241 and the second gate line slit 1242 may penetrate through, for example, the stop layer 129, the selection stacking structure 120, and the initial stacking structure 128 in the z direction.

Further, a film deposition process such as PVD, CVD, ALD or any combination thereof may be used to fill a sacrificial material in a portion of the first gate line slit 1241 located in the core area 101, and a portion of the first gate line slit 1241 located in the non-core area 102 may be left in an unfilled state. For example, compared with the dielectric layer 104 and the gate sacrificial layer 105, the sacrificial material may have different etching selection ratios with respect to the same etchant. For example, the sacrificial material may comprise, but is not limited to, polysilicon or carbon. Further, the portion of each gate sacrificial layer 105 located in the first area 1021 of the non-core area 102 can be removed through the portion of the first gate line slit 1241 located in the non-core area 102 using a wet etching process. It should be noted that the first area 1021 may be an area having a predetermined distance from the first gate line slit 1241. For example, the area and range of the first area 1021 may be determined by controlling at least one of the etching rate or etching time of the wet etching. Further, to remove the sacrificial material in the portion of the first gate line slit 1241 located in the core area 101, the portion of each gate sacrificial layer 105 located in the core area 101 can be removed through at least one of the portion of the first gate line slit 1241 located in the core area 101 or the second gate slit 1242 using a wet etching process.

Further, as shown in FIG. 9D, using a film deposition process such as PVD, CVD, ALD or any combination thereof, the gate layer 106 may be formed in a gap formed by removing the gate sacrificial layer 105 in the core area 101 and the first area 1021 of the non-core area 102. In some examples, a high dielectric constant layer, an adhesive layer, and a conductive layer may be sequentially formed within the gap to form a gate layer (not shown). In some other examples, as shown in FIG. 9D, a conductive layer may be directly formed in the gap and used as the gate layer 106.

Further, as shown in FIGS. 9C and 9D, the first gate line slit 1241 and the second gate line slit 1242 may be filled to form the first gate line slit structure 1261 and the second gate line slit structure 1262 using a film deposition process such as PVD, CVD, ALD or any combination thereof. For example, the filling material in the first gate line slit 1241 and the second gate line slit 1242 may comprise silicon oxide, silicon nitride, silicon oxynitride or any other appropriate insulating material.

After “gate replacement,” a stacking structure 100 can be formed. The portions of the stacking structure 100 located in the core area 101 and the first area 1021 of the non-core area 102 comprise a plurality of dielectric layers 104 and a plurality of gate layers 106 alternately stacked. The portions of the stacking structure 100 located in the second area 1022 of the non-core area 102 and the first sealing area 103 comprise a plurality of dielectric layers 104 and a plurality of gate sacrificial layers 105 alternately stacked.

The operations of forming the stacking structure 100 have been described above in some examples. In some other examples, the gate sacrificial layer in the portion of the initial stacking structure located in the core area can be removed first, and then the gate sacrificial layer in the portion of the initial stacking structure located in the first area can be removed, which is not limited in this disclosure.

S120: forming at least one circle of sealing structure in the first sealing area of the stacking structure, wherein at least one circle of sealing structure surrounds the memory array area, and the sealing structure comprises a sealing ring body penetrating through the stacking structure and at least two circles of first dummy interconnection structures connected with the sealing ring body.

In operation S120, in some examples, as shown in FIG. 9E, two circles of contact grooves 302 may be formed in the first sealing area 103 using photolithography and etching processes. Each circle of contact grooves 302, for example, penetrates through the stop layer 129, the selection stacking structure 120 and the stacking structure 100, and continuously surrounds, for example, the memory array area 130 (refer to FIG. 4A). For example, in the process of forming the contact groove 302, a plurality of contact holes 112 may be formed in the second area 1022 of the non-core area 102 using a photolithography and etching process. For example, a plurality of contact holes 112 and contact grooves 302 may be formed in the same photolithography and etching process through a mask design. The contact holes 112 extend in the z direction to one of the plurality of gate sacrificial layers 105 (i.e., the target gate sacrificial layer corresponding to the contact holes 112), and the plurality of contact holes 112 respectively extend to their respective corresponding one of the plurality of gate sacrificial layers. Further, an epitaxial contact hole 113 exposing the gate layer 106 located in the first area 1021 may be formed using, for example, a wet etching process and removing a portion of its corresponding gate sacrificial layer 105 through each contact hole 112. For example, the size of the section (e.g., diameter) of the epitaxial contact hole 113 perpendicular to the z direction is larger than the size of the section (e.g., diameter) of the contact hole 112 perpendicular to the z direction.

In some examples, as shown in FIG. 9E and FIG. 9G, a first conductive portion 115 may be formed in the epitaxial contact hole 113 using a film deposition process such as PVD, CVD, ALD or any combination thereof. Since the epitaxial contact hole 113 exposes the gate layer 106 located in the first area 1021, the first conductive portion 115 is in contact with the gate layer 106 located in the first area 1021. Alternatively, a high dielectric constant layer, an adhesive layer, and a conductive layer may be sequentially formed on the inner wall of the epitaxial contact hole 113 using a film deposition process such as PVD, CVD, ALD, or any combination thereof, to form a first conductive portion (not shown).

In operation S120, in some examples, as shown in FIG. 9E and FIG. 9G, a metal layer 303 with an opening can be formed on the groove wall of the contact groove 302 using a film deposition process such as PVD, CVD, ALD or any combination thereof. For example, in the process of forming the metal layer 303, a second conductive portion 116 with an opening may be formed on the hole wall of the contact hole 112 using the same film deposition process. The second conductive portion 116 is in contact with the first conductive portion 115 to simplify the manufacturing process. For example, the opening of the metal layer 303 may be filled with insulating material using the same film deposition process to form the second filling portion 305, and the opening of the second conductive portion 116 may be filled with insulating material to form the first filling portion 117. The materials of the first filling portion 117 and the second filling portion 305 may be the same. Further, the metal plug 304 closing the metal layer 303 may be formed using a film deposition process such as PVD, CVD, ALD or any combination thereof. For example, in the process of forming the metal plug 304, the conductive plug 114 closing the second conductive portion 116 may be formed using the same film deposition process to simplify the manufacturing process.

After the above process, the first conductive portion 115, the second conductive portion 116, the first filling portion 117 and the conductive plug 114 can constitute a contact structure 111. The metal layer 303, the second filling portion 305, and the metal plug 304 may constitute the sealing ring body 301. As described above, a plurality of contact structures 111 and sealing ring bodies 301 may be formed in the same process. In some other examples, the contact structure and the sealing ring body may comprise a single material (e.g., metal). In addition, it should be pointed out that the contact structure and the sealing ring body can also be formed in different processes, which is not limited in the present disclosure.

In some examples, as shown in FIG. 9E, before forming a plurality of contact holes 112 and contact grooves 302, a first dielectric layer 108 covering, for example, the stop layer 129 may be formed on the first side of the stacking structure 100 using a film deposition process such as PVD, CVD, ALD or any combination thereof. Further, as shown in FIG. 9F, an open hole 109 penetrating through the first dielectric layer 108 may be formed using a photolithography and etching process. For example, the open hole 109 may expose the end of the selection channel structure 121. Still for example, when the semiconductor device does not comprise the selection stacking structure 120 and the selection channel structure 121, the open hole may expose the end of the channel structure. The stop layer 129 can be used as an etching stop layer for forming the open hole 109 to improve the process controllability. In some examples, in the process of forming the contact hole 112 and the contact groove 302, for example, the open hole 109 is formed in the same photolithography and etching process through the mask design. In some other examples, the open hole 109 may be formed during the back etching of the first filling portion 117 and the second filling portion 305 (refer to FIG. 9G). Further, as shown in FIG. 9G, the channel contact 110 filled in the open hole 109, the conductive plug 114 and the metal plug 304 (refer to FIG. 9F) can be synchronously formed using the same film deposition process to simplify the manufacturing process.

In operation S120, to form the first dummy interconnection structure 306 shown in FIG. 9H, in some examples, as shown in FIG. 9H, a first sublayer of the second dielectric layer 127 covering the first dielectric layer 108 may be formed on the first side of the stacking structure 100 using a film deposition process such as PVD, CVD, ALD, or any combination thereof. Then, a first through-hole structure 307 penetrating through the first sublayer of the second dielectric layer 127 to the sealing ring body 301 can be formed using a photolithography and etching process and a film deposition process. Next, a second sublayer covering the first sublayer of the second dielectric layer 127 may be formed using a film deposition process such as PVD, CVD, ALD, or any combination thereof, and a first interconnection line structure 308 penetrating through the second sublayer to the first through-hole structure 307 may be formed using a photolithography and etching process and a film deposition process. Further, the first through-hole structure 307 and the first interconnection line structure 308 may be alternately formed to form the first dummy interconnection structure 306 penetrating through the second dielectric layer 127. For example, each first through-hole structure 307 and each first interconnection line structure 308 in the first dummy interconnection structure 306 may be a ring structure. Each circle of sealing ring body 301 is connected with two circles of first dummy interconnection structures 306 in the z direction.

In some examples, in the process of forming the first dummy interconnection structure 306, a first interconnection structure 118 in contact with the contact structure 111 and a second interconnection structure 119 in contact with the channel contact 110 may be formed in the same process. For example, in the process of forming the first through-hole structure 307 in the first dummy interconnection structure 306, the through-hole structures in the first interconnection structure 118 and the second interconnection structure 119 may be formed using the same photolithography and etching process and film deposition process. In the process of forming the first interconnection line structure 308 in the first dummy interconnection structure 306, the interconnection line structures in the first interconnection structure 118 and the second interconnection structure 119 can be formed using the same photolithography and etching process and film deposition process. Thus, the layers and materials of the through-hole structure and the interconnect structure in the first dummy interconnection structure 306, the first interconnect structure 118 and the second interconnect structure 119 are the same.

After the above process, respective components formed on a side of the first substrate 122 can constitute the initial memory array structure 500′.

In some examples, as shown in FIG. 9H, the manufacturing method 1000 may further comprise an operation of forming a peripheral device structure 200. For example, the initial memory array structure 500′ and the peripheral device structure 200 can be manufactured in parallel, so that the thermal budget for manufacturing one structure does not limit the process of manufacturing the other, and is conducive to improving the manufacturing efficiency.

In some examples, as shown in FIG. 9H, the second substrate 202 may be divided into a device area 131 and a second sealing area 131 in a plane perpendicular to the z direction, wherein the second sealing area 131 surrounds the device area 131. The material of the second substrate 202 may comprise, but is not limited to, silicon (e.g., monocrystalline silicon c-Si), silicon germanium (SiGe), gallium arsenide (GaAs), germanium (GE), silicon on insulator (SOI), or any other suitable material. For example, the second substrate 202 may be a silicon substrate. In some examples, a plurality of peripheral devices 201 may be formed in the device area 131 on a side of the second substrate 202 using any process known in the art. Several peripheral devices 201 may constitute at least one of a digital, analog, or mixed digital analog functional circuits configured to realize various functions.

In some examples, a second dummy interconnection structure 309 may be formed, using a photolithography and etching process and a film deposition process, in the second sealing area 131 on the side of the second substrate 202 where a plurality of peripheral devices 201 are formed, wherein the number of second dummy interconnection structures 309 may match the number of first dummy interconnection structures 306 (e.g., the total numbers are equal). In this example, the peripheral device structure 200 comprises four circles of second dummy interconnection structures 309. For example, similar to forming the first dummy interconnection structure 306, the second through-hole structure 310 and the second interconnection line structure 311 may be alternately formed to form the second dummy interconnection structure 309. For example, each second through-hole structure 310 and each second interconnection line structure 311 in the second dummy interconnection structure 309 may comprise an annular structure. In some examples, in the process of forming the second dummy interconnection structure 309, other interconnection structures in contact with the peripheral device 201 may be formed in the same process.

In some examples, as shown in FIG. 9H, the manufacturing method 1000 may further comprise the operation of bonding the initial memory array structure 500′ with the peripheral device structure 200. For example, the initial memory array structure 500′ and the peripheral device structure 200 may be connected in the z direction by bonding (e.g., hybrid bonding), so that a bonding layer 400 is formed between the initial memory array structure 500′ and the peripheral device structure 200. The hybrid bonding may perform data transmission between the initial memory array structure 500′ and the peripheral device structure 200 through the bonding contact 401.

In some examples, each circle of first dummy interconnection structure 306 and each circle of second dummy interconnection structure 309 are bonded and connected, for example, through the bonding contact 401 of the bonding layer 400. In this example, by forming the second dummy interconnection structure 309 in the second sealing area 131 and bonding and connecting it with the first dummy interconnection structure 306, the second dummy interconnection structure 309 and the sealing structure 300 can be used as a whole structure to prevent cracks from cracking into the memory array area 130 and the device area 131, reducing the risk of generating edge cracks in the die and being conducive to improving the yield of the product.

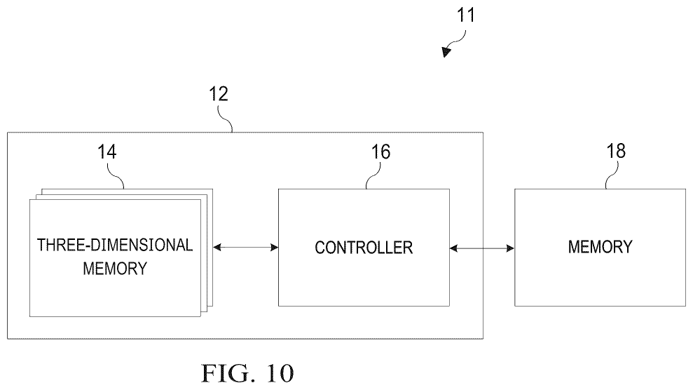

Some examples of the present disclosure also provide a memory system. FIG. 10 is a block diagram of a system according to an example of the present disclosure, which has a memory system.

The system 11 may be a mobile phone, a desktop computer, a laptop computer, a tablet computer, an on-board computer, a game console, a printer, a positioning device, a wearable electronic device, an intelligent sensor, a virtual reality (VR) device, an augmented reality (AR) device, or any other appropriate electronic device (the electronic device has a memory system 12 located therein). As shown in FIG. 10, the system 11 may comprise a host 18 and a memory system 12 having one or more three-dimensional memories 14 and a controller 16. The host 18 may be a processor of an electronic device, such as a central processing unit (CPU), or be a system on chip (SOC), such as an disclosure processor (AP). The host 18 may be configured to send or receive data to and from the three-dimensional memory 14.

The three-dimensional memory 14 may comprise a semiconductor device described in any example of the present disclosure, for example, the semiconductor device 10 shown in FIGS. 2A to 2D, the semiconductor device 10a shown in FIG. 3, the semiconductor device 10b shown in FIGS. 4A and 4B, or the semiconductor device 10c shown in FIGS. 5A or 5B. According to some examples, the controller 16 is coupled to the three-dimensional memory 14 and the host 18, and is configured to control the three-dimensional memory 14. The controller 16 may manage the data stored in the three-dimensional memory 14 and communicate with the host 18. In some examples, the controller 16 is designed to operate in a low duty cycle environment, such as a secure digital (SD) card, compact flash (CF) card, universal serial bus (USB) flash drive, or other media used in electronic devices such as personal calculators, digital cameras, mobile phones, etc. In some examples, the controller 16 is designed to operate in a high duty cycle environment, such as an SSD or embedded multi-media card (EMMC) used as a data storage device for mobile devices such as smart phones, tablets, laptops and the like, and enterprise memory arrays. The controller 16 may be configured to control operations of the three-dimensional memory 14, such as reading, erasing, and programming operations. The controller 16 may also be configured to manage various functions related to data stored in or to be stored in the three-dimensional memory 14, comprising but not limited to bad block management, garbage collection, logical to physical address translation, wear leveling, etc. In some examples, the controller 16 is further configured to process error correction code (ECC) related to data read from or written to the three-dimensional memory 14. The controller 16 may also perform any other appropriate functions, such as formatting the three-dimensional memory 14. The controller 16 may communicate with an external device (e.g., host 18) according to a communication protocol. For example, the controller 16 may communicate with an external device through at least one of various interface protocols, such as USB protocol, MMC protocol, peripheral component interconnection (PCI) protocol, PCI Express (PCI-E) protocol, advanced technology attachment (ATA) protocol, serial ATA protocol, parallel ATA protocol, small computer small interface (SCSI) protocol, enhanced small disk interface (ESDI) protocol, integrated drive electronic device (IDE) protocol, Firewire protocol, etc.

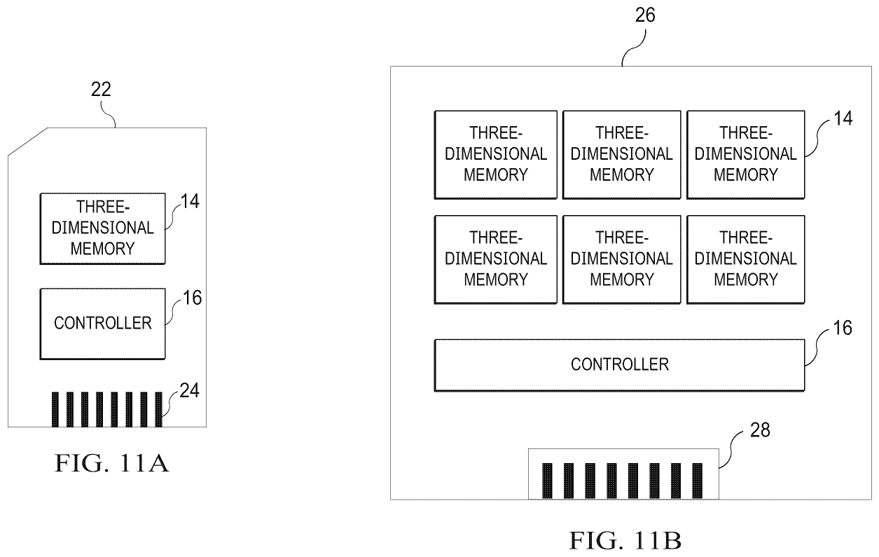

The controller 16 and one or more three-dimensional memories 14 may be integrated into various types of memory systems, for example, comprised in the same package, such as a universal flash storage (UFS) package or an EMMC package. For example, the memory system 12 may be implemented and packaged into different types of final electronic products. In one example as shown in FIG. 11A, the controller 16 and a single three-dimensional memory 14 may be integrated into the memory card 22. Memory card 22 may comprise PC card (PCMCIA, Personal Computer Memory Card International Association), CF card, smart media (SM) card, memory stick, multimedia card (MMC, RS-MMC, MMCmicro), SD card (SD, miniSD, microSD, SDHC), UFS, etc. The memory card 22 may further comprise a memory card connector 24 that couples the memory card 22 to a host (e.g., the host 18 in FIG. 10). In another example as shown in FIG. 11B, the controller 16 and a plurality of three-dimensional memories 14 may be integrated into the SSD 26. SSD 26 may further comprise an SSD connector 28 that couples SSD 26 to a host (e.g., host 18 in FIG. 10). In some examples, at least one of the storage capacity or operating speed of SSD 26 is higher than the at least one of the memory card 22.

The above description is only the description of some implementations of the present disclosure and the applied technical principles. Those skilled in the art should understand that the scope of protection involved in this disclosure is not limited to the technical solution formed by the combination of the above technical features, but also covers other technical solutions formed by any combination of the above technical features or their equivalent features without departing from the technical concept, for example, a technical solution formed by replacing the above features and the technical features with similar functions disclosed (but not limited to) in the present disclosure with each other.

What is claimed is:

1. A semiconductor device, comprising:
a stacking structure comprising a memory array area and a first sealing area; and
at least one circle of sealing structure in the first sealing area and surrounding the memory array area, wherein the sealing structure comprises a sealing ring body penetrating through the stacking structure and at least two circles of first dummy interconnection structures connected with the sealing ring body.

2. The semiconductor device according to claim 1, further comprising:
a peripheral device structure comprising: a device area provided with a peripheral device;
and a second sealing area; and
at least two circles of second dummy interconnection structures in the second sealing area and respectively bonded and connected with the at least two circles of first dummy interconnection structures.

3. The semiconductor device according to claim 1, wherein the memory array area comprises a core area and a non-core area, the stacking structure comprises a plurality of dielectric layers and a plurality of gate layers alternately stacked in the core area and a first area of the non-core area, and the stacking structure comprises the plurality of dielectric layers and a plurality of gate sacrificial layers alternately stacked in a second area of the non-core area, and wherein the semiconductor device further comprises:
a plurality of contact structures in the second area, wherein the plurality of contact structures respectively extend to gate sacrificial layers of different layers and each of the plurality of contact structures is connected with the gate layer of the same layer as the corresponding gate sacrificial layer in the core area through the gate layer of the same layer as the corresponding gate sacrificial layer in the first area; and
a first interconnection structure in contact with the contact structure, wherein the first interconnection structure is of the same material as the first dummy interconnection structure.

4. The semiconductor device according to claim 3, wherein the core area comprises a channel structure penetrating through the stacking structure, wherein the semiconductor device further comprises:
a channel contact in contact with an end of the channel structure; and
a second interconnection structure in contact with the channel contact, wherein the second interconnection structure is of the same material as the first interconnection structure and the first dummy interconnection structure.

5. The semiconductor device according to claim 4, wherein each of the contact structures comprises:
a conductive plug in contact with the first interconnection structure;
a first conductive portion in a layer of gate sacrificial layer in the second area and connected with the gate layer of the same layer as the layer of gate sacrificial layer in the core area through the gate layer of the same layer as the layer of gate sacrificial layer in the first area; and
a second conductive portion in contact with the conductive plug and the first conductive portion and penetrating through the stacking structure of a corresponding number of layers.

6. The semiconductor device according to claim 5, wherein the conductive plug is of the same material as the channel contact.

7. The semiconductor device according to claim 5, wherein the contact structure further comprises:
a first filling portion filled in a space enclosed by the conductive plug, the first conductive portion and the second conductive portion.

8. The semiconductor device according to claim 4, wherein the sealing ring body comprises:
a metal layer penetrating through the stacking structure; and
a metal plug in contact with the metal layer, wherein the metal plug is in the same layer and of the same material as the channel contact.

9. The semiconductor device according to claim 8, wherein the sealing ring body further comprises:
a second filling portion filled in a space enclosed by the metal layer and the metal plug.

10. The semiconductor device according to claim 4, wherein the first dummy interconnection structure, the first interconnection structure and the second interconnection structure each comprise at least one layer of through-hole structure and at least one layer of interconnect line structure alternately arranged in a stacking direction, and the numbers of layers of the through-hole structures in the first dummy interconnection structure, the first interconnection structure and the second interconnection structure are the same, and the numbers of layers of the interconnection structures in the first dummy interconnection structure, the first interconnection structure and the second interconnection structure are the same.

11. A manufacturing method of a semiconductor device, comprising:
forming a stacking structure comprising a memory array area and a first sealing area; and
forming at least one circle of sealing structure in the first sealing area of the stacking structure, wherein the at least one circle of sealing structure surrounds the memory array area, and the sealing structure comprises a sealing ring body penetrating through the stacking structure and at least two circles of first dummy interconnection structures connected with the sealing ring body.

12. The manufacturing method according to claim 11, further comprising:
forming a peripheral device in a device area of a peripheral device structure;
forming, in a second sealing area of the peripheral device structure, second dummy interconnection structures matching positions and numbers of the first dummy interconnection structures; and
bonding and connecting the first dummy interconnection structures and the second dummy interconnection structures.

13. The manufacturing method according to claim 11, wherein forming the stacking structure comprising the memory array area and the first sealing area comprises:
forming an initial stacking structure comprising the memory array area and the first sealing area, wherein the initial stacking structure comprises a dielectric layer and a gate sacrificial layer sequentially stacked, and the memory array area comprises a core area and a non-core area; and
replacing the gate sacrificial layer in the core area and the gate sacrificial layer in a first area in the non-core area in the initial stacking structure with a gate layer to form the stacking structure.

14. The manufacturing method according to claim 13, wherein forming the at least one circle of sealing structure in the first sealing area of the stacking structure comprises:
forming a plurality of contact structures in a second area in the non-core area and the at least one circle of sealing ring body in the first sealing area in the same process, wherein the plurality of contact structures respectively extend to the gate sacrificial layers of different layers, and each of the plurality of contact structures is connected with the gate layer of the same layer as the corresponding gate sacrificial layer in the core area through the gate layer of the same layer as the corresponding gate sacrificial layer in the first area; and
forming a plurality of first interconnection structures respectively in contact with the plurality of contact structures and the at least two circles of first dummy interconnection structures in the same process.

15. The manufacturing method according to claim 14,
wherein before replacing the gate sacrificial layer in the core area and the gate sacrificial layer in the first area in the non-core area in the initial stacking structure with the gate layer, forming the stacking structure comprising the memory array area and the first sealing area further comprises:
forming a channel structure that is in the core area and penetrates through the initial stacking structure;
wherein before forming the at least two circles of first dummy interconnection structures and the plurality of first interconnection structures in contact with the plurality of contact structures in the same process, the manufacturing method further comprises:
forming a channel contact in contact with an end of the channel structure;
wherein forming the at least two circles of first dummy interconnection structures and the plurality of first interconnection structures respectively in contact with the plurality of contact structures in the same process further comprises:
forming a second interconnection structure in contact with the channel contact.

16. The manufacturing method according to claim 15, wherein forming the plurality of contact structures in the second area in the non-core area and the at least one circle of sealing ring body in the first sealing area in the same process comprises:
forming at least one circle of contact groove in the first sealing area at the same time of forming a plurality of contact holes in the second area, wherein the plurality of contact holes respectively extend to a corresponding target gate sacrificial layer, the target gate sacrificial layer is one of a plurality of the gate sacrificial layers and the at least one circle of contact groove surrounds the memory array area and penetrates through the stacking structure;
removing a portion of the target gate sacrificial layer through each of the contact holes to form an epitaxial contact hole exposing the gate layer in the first area and corresponding to the target gate sacrificial layer; and
forming the at least one circle of sealing ring body in the at least one circle of contact groove at the same time of forming the plurality of contact structures in the plurality of contact holes and the epitaxial contact hole.

17. The manufacturing method according to claim 16, wherein the contact structure comprises a first conductive portion, a second conductive portion and a conductive plug, and the sealing ring body comprises a metal layer and a metal plug;
wherein forming the at least one circle of sealing ring body in the at least one circle of contact groove at the same time of forming the plurality of contact structures in the plurality of contact holes and the epitaxial contact hole comprises:
forming the first conductive portion in the epitaxial contact hole, wherein the first conductive portion is in contact with the gate layer in the first area;
forming a metal layer with an opening on a groove wall of the contact groove at the same time of forming the second conductive portion with an opening on a hole wall of the contact hole; and
forming the metal plug closing the opening of the metal layer at the same time of forming the conductive plug closing the opening of the second conductive portion.

18. The manufacturing method according to claim 17,
wherein before forming the at least one circle of contact groove in the first sealing area at the same time of forming the plurality of contact holes in the second area in the non-core area, the manufacturing method further comprises:
forming a first dielectric layer on a first side of the stacking structure;
wherein before forming the metal plug closing the opening of the metal layer at the same time of forming the conductive plug closing the opening of the second conductive portion, the manufacturing method further comprises:
forming an open hole penetrating through the first dielectric layer, wherein the open hole exposes an end of the channel structure;
wherein forming the metal plug closing the opening of the metal layer at the same time of forming the conductive plug closing the opening of the second conductive portion further comprises:
filling a metal material in the open hole to form the channel contact.

19. The manufacturing method according to claim 17,
wherein before forming the at least one circle of contact groove in the first sealing area at the same time of forming the plurality of contact holes in the second area in the non-core area, the manufacturing method further comprises:
forming a first dielectric layer covering the stacking structure on a first side of the stacking structure;
wherein forming the at least one circle of contact groove in the first sealing area at the same time of forming the plurality of contact holes in the second area in the non-core area further comprises:
forming an open hole penetrating through the first dielectric layer, wherein the open hole exposes an end of the channel structure;
wherein forming the metal plug closing the opening of the metal layer at the same time of forming the conductive plug closing the opening of the second conductive portion further comprises:
filling a metal material in the open hole to form the channel contact.

20. A memory system, comprising:
a three-dimensional memory comprising a semiconductor device; and
a controller coupled with the three-dimensional memory and configured to control the three-dimensional memory,
wherein the semiconductor device comprises:
a stacking structure comprising a memory array area and a first sealing area; and
at least one circle of sealing structure in the first sealing area and surrounding the memory array area, wherein the sealing structure comprises a sealing ring body penetrating through the stacking structure and at least two circles of first dummy interconnection structures connected with the sealing ring body.
